(19) United States
(12) Patent Application Publication
(10) Pub. No.: US 2005/0083743 A1
(43) Pub. Date: Apr. 21, 2005

(54) Nonvolatile sequential machines

(75) Inventors: Radu Andrei, Dallas, TX (US); Richard Spitzer, Berkeley, CA (US); E. James Torok, Shoreview, MN (US); Stephen J. Nuspl, Fridley, MN (US)

Correspondence Address: BEYER WEAVER & THOMAS LLP, P.O. BOX 70250, OAKLAND, CA, 94612-0250, US

(73) Assignee: Integrated Magnetoelectronics Corporation A California corporation

(21) Appl. No.: 10/935,914

(22) Filed: Sep. 7, 2004

Related U.S. Application Data
(60) Provisional application No. 60/501,670, filed on Sep. 9, 2003.

(51) Int. Cl. G11C 7/00

(52) U.S. Cl. 365/202

(57) ABSTRACT

A nonvolatile sequential machine is described which includes a semiconductor controller operable to control operation of the nonvolatile sequential machine according to a state machine comprising a plurality of states. The nonvolatile sequential machine further includes a plurality of state registers operable to store the plurality of states. The state registers comprise nonvolatile random-access memory operation of which is based on giant magnetoresistance.

### RELATED APPLICATION DATA

The present application claims priority under 35 U.S.C. 119(e) to U.S. Provisional Application No. 60/501,670 for NONVOLATILE SEQUENTIAL MACHINE filed on Sep. 9, 2003 (Attorney Docket No. IMECP020P), the entire disclosure of which is incorporated herein by reference for all purposes.

### BACKGROUND OF THE INVENTION

The present invention relates to memory technology based at least in part on the property of giant magnetoresistance (GMR). More specifically, such memory technology is employed in the context of a generalized state machine to render the state machine nonvolatile.

Computers of all kind, including personal computers (PCs), store their operating systems (OS) and application programs on nonvolatile media like hard disks (HD). Computing configurations with a small OS and few application programs can store all this software directly in the system memory provided this memory is nonvolatile. Most of the systems known as “general” computing configurations use a HD for storing, as they cannot afford a nonvolatile system memory for technology reasons, cost reasons, or both. Most of the computing configurations known as “embedded” use nonvolatile system memory for storing the OS and application programs. Other computing configurations might use a combination of the two storage methods.

Computers are built as a collection of components which, in aggregate, perform all needed system functions. Normal computer operation is typically referred to as the “active mode.” Configurations embodying sequential machines (e.g., algorithmic state machines which form the basis for controllers, microcontrollers and other sequential machines) have their power cut for the time they are out of operation. Often, power is cut temporarily for various reasons, with the intention of reapplying it when needed; in this case the computer is said to be “on standby” for as long as power is not applied. “Waking up” means activating a component after it was switched into the standby mode. When wakened the component needs access to the information on the last state of the machine prior to having been put on standby. This is a necessary condition for resuming the active mode. Normally, this information is stored in registers. As semiconductor registers are volatile memory cells, they need to be backed up in a nonvolatile scratch pad prior to interrupting power, and then restored after power has been reapplied. These operations would be unnecessary if the registers were nonvolatile. In principle, this can be achieved by using a nonvolatile semiconductor memory such as flash; in practice, this is not proven to be feasible because flash does not allow byte access, is too slow, and has a limited number of write cycles.

In the same context, more complex computing configurations allow only a limited number of internal components to be switched into the standby mode and then wakened.

Upon power up from the un-powered mode, the entire computing configuration has to be made operations ready, a process known as “booting”. In its most general form, the tasks involved in booting ensure that (a) all relevant OS and application-program parts are in the system memory; and (b) all system modules (central processing unit, specialized processing units, storage units, input/output units, communication units, etc.) are initialized. The latter operation typically involves loading all registers for each individual system module with the data required to put the system modules in position to commence task execution. Thus, in order to ready the system, computing configurations that do not have a nonvolatile system memory and store essential software in a separate storage module have to perform both operation (a) and (b); those that store essential software in a nonvolatile memory system, only operation (b). These operations have to be performed every time power is reapplied to the computing configuration after having been removed, for whatever reason.

It is well known in the state of the art that the relevant software can be preserved during power-down by replacing DRAM (the dominant technology for main memory in PCs and other general computing configurations) with nonvolatile memory; this is presently done in small computers. Saving register contents has turned out to be more elusive. The time needed to initialize the work memory and that to initialize all system registers greatly depends on the computing configuration. Memory initialization time for the typical PC results from the transfer of the needed OS routines, peripheral drivers, and basic applications (e.g., 10 MB of program) from the hard disk to the main PC memory. Typical times are around 6 sec.

Register initialization time results from the sequential transfer of the content of all system registers (e.g., 256 64-bit registers) and the parameters needed for the network connection of the PC from main memory to the respective registers and communication module memory. This register initialization also includes the time needed to initialize the PC monitor, the graphics module, and the frame memory of the monitor. Current register initialization times for IBM-type PCs with Windows operating system can be as low as 12 seconds, but also much higher, while that for Apple-type computers with Apple operating system can be as low as 7 seconds, but also much higher. Thus, the total minimum time to boot can be as low as 18 and 13 seconds, respectively, but also much higher. These times grow significantly when computers are part of a networked cluster because of the network initialization routines that need to be loaded or restored.

Typical computing architectures have a limited number of internal busses that connect the system modules with system memory. Most have only a single system bus for economic reasons. In a single-bus configuration, the most common configuration for PCs, the system registers are initialized sequentially, making this operation much more time consuming than if it were done in parallel. In a multi-bus system, which is often implemented in embedded computing configurations, the register initialization time might be reduced if register initialization can be performed simultaneously on more than one bus. Because of continuously increasing complexity of general, embedded and hybrid computing configurations, the number of system registers is increasing steadily, which in turn leads to a steady increase in the system initialization time both for single-bus and multi-bus systems.

The main reason computers are turned off for longer periods (e.g. overnight) is to reduce wear-out and to save power. The main reason computers are temporarily turned off is to save power. Saving power in electronic devices is becoming increasingly important for a multitude of reasons. The following example is for a PC, but the concepts are generic and apply to any other computing configuration as well.

Power consumption needs to be reduced for two main reasons: (a) to preserve battery power, and (b) to minimize heat generation in order to keep component packaging affordable. The more power a package has to dissipate, the more expensive it becomes. Beyond a certain level, no package material can help. This is the reason some high-performance microprocessors currently use on-chip mini fans, while others employ forced water cooling. Both methods significantly increase component costs and power consumption.

Fully functioning computing configurations are normally built by assembling a number of components, each of them able to perform a collection of system functions. As component manufacturing technologies evolve, the distribution of functions among the components (function partitioning) is changing. Function partitioning is also changing in order to improve system performance and reduce system power consumption. A further reason to redistribute the number of functions per component is to minimize the number of components that are in the active mode at any given time, thus saving more system power.

System power is saved in today's computers mainly by cutting it off from those system modules that are idle for periods of time. Because of the volatile nature of the semiconductor system-module register set, this operation involves safeguarding the register contents for all modules, i.e. creating a content backup, in a memory area that is either nonvolatile or permanently powered. After power is restored, the register set is initialized by transferring the safeguarded contents back from this memory to the registers.

The disadvantage of having to perform the system initialization operations (a) and (b) detailed above can be significant in many situations. Both the backup and initialization operations are resource intensive and very time consuming. If this technique is used, it requires complex software routines to back up the register content of the modules, which are temporarily put into power-saving modes, and to restore the contents once they are brought back into the active mode. For practical reasons, this technique of saving power by selectively cutting it off from system-modules registers while the modules are idle is therefore seldom used. Moreover, the technique cannot be used in systems that need to operate in real time or monitor external events. In addition, as PC hardware and software increase in complexity, users have to wait increasingly longer times for the PC to become operational. In applications where the initialization delay is not acceptable, special hardware is incorporated in order to take care of the system during the initialization period; this increases system costs and power consumption. Component volatility thus prevents the system from realizing its entire power-saving potential.

A more common technique of reducing power consumption is to divide the entire system into zones with individual power supplies. Because they have independent power supplies, powering can be done on an as-needed basis; i.e., zones that are not performing any function at a given time can be put on standby. For power-saving reasons, zoning granularity became finer over time, reaching component level; i.e., components are individually powered on an as-needed basis.

The state-of-the-art today is to zone the semiconductor component itself, i.e., the substrate of the component is partitioned into zones that can be individually powered. This means that parts of a semiconductor die can be in the active mode, with other parts in the standby mode. Powering up and down of the different zones, both on system and component level, requires complex timing, which in turn requires separate power-management logic. Currently, the logic that controls component-zone powering is implemented within the component itself, while the logic that controls system zone is implemented in a separate component.

Current practice is for the power-management logic in computing systems, either on chip or as a separate component, to detect the transition into the power-down mode by generating a power-down signal. In addition, the power-supply module is typically equipped with a power capacitor that creates a power reserve for a certain number of system cycles, generally around ten. That is, once the power-down condition has been detected and a power-down signal generated, the system will still be able to perform approximately ten more cycles until it grinds to a complete halt. These ten cycles add up to 10 ns for a 1 GHz system clock. This time is not nearly enough to back up the system registers into the nonvolatile portion of the main system memory, even if this exists.

A capacitor-type power-down reserve that provides enough reserve for the computer to save all registers into the nonvolatile portion of the main memory is not economically feasible in stationary computers (like desktop PCs, work stations, servers), and even less so in portable (notebooks, laptop PCs) or mobile computers (palm top PCs), which have severe space constraints.

### SUMMARY OF THE INVENTION

According to the present invention, a nonvolatile sequential machine is provided which includes a semiconductor controller operable to control operation of the nonvolatile sequential machine according to a state machine comprising a plurality of states. The nonvolatile sequential machine further includes a plurality of state registers operable to store the plurality of states. The state registers comprise nonvolatile random-access memory operation of which is based on giant magnetoresistance.

According to a specific embodiment of the invention, a device is provided which includes a semiconductor controller operable to control operation of the device according to a state machine comprising a plurality of states. A plurality of semiconductor registers are operable to store the states during an active mode of the device. A plurality of shadow registers are operable to store the states during a reduced power mode of the device. The shadow registers comprise nonvolatile random-access memory operation of which is based on giant magnetoresistance (GMR). Interface circuitry is operable to transmit the states between the semiconductor registers and the shadow registers.

A further understanding of the nature and advantages of the present invention may be realized by reference to the remaining portions of the specification and the drawings.

### BRIEF DESCRIPTION OF THE DRAWINGS

FIG. 1 is a simplified schematic of an all-metal GMR memory.

FIGS. 2 and 3 show the operation of a GMR memory cell.

FIG. 4 shows the magnetization states of a GMR memory cell.

FIG. 5 illustrates operation of a GMR memory cell.

FIG. 6 shows a dibit memory cell.

FIG. 7 shows a triple or quad bit memory cell.

FIG. 8 shows a dibit memory cell.

FIG. 9 shows the relationship between magnetic fields and current in a GMR thin film structure.

FIG. 10 shows a quad bit memory cell.

FIG. 11 is a simplified diagram of an array of memory cells.

FIG. 12(a) is a simplified diagram of another array of memory cells.

FIG. 12(b) shows yet another dibit memory cell.

FIG. 13 is a simplified circuit diagram of a transpinnor for use with specific embodiments of the present invention.

FIGS. 14(a) and 14(b) are simplified representations of a differential transpinnor for use with specific embodiments of the present invention.

FIGS. 15(a)-15(d) illustrate four different embodiments in which a transpinnor is used to balance a sense-digit/reference line pair.

FIGS. 16(a)-16(e) illustrate the effect of the trimming technique of the present invention on the balancing of sense-digit/reference line pairs.

FIG. 17 is a simplified schematic of a memory access line selection matrix for use with specific embodiments of the present invention.

FIG. 18 shows a generalized computer memory hierarchy.

FIGS. 19(a) and 19(b) are is functional block diagrams of ISA-bus IBM compatible personal computer systems according to specific embodiments of the invention.

FIG. 20 is a block diagram of a specific implementation of a SpinRAM hard card in accordance with a specific embodiment of the invention.

FIG. 21 is a functional block diagram of a personal computer system having a PCMCIA architecture in accordance with a specific embodiment of the invention.

FIG. 22 is a block diagram of computer system using SpinRAM technology in accordance with a specific embodiment of the invention.

FIG. 23 is a simplified block diagram of a generalized computer system based on SpinRAM technology in accordance with a specific embodiment of the invention.

FIG. 24 is a simplified block diagram illustrating implementation of a nonvolatile sequential machine according to a specific embodiment of the present invention.

FIG. 25 is a block diagram illustrating a particular implementation of a semiconductor register with a shadow register.

FIGS. 26-35 are exemplary interface circuits for translating signal levels between semiconductor circuits and all-metal GMR circuits for use with various embodiments of the invention.

FIG. 36 is a more detailed representation of the connection between semiconductor register bits and shadow register bits according to a specific embodiment of the invention.

FIG. 37 is a simplified block diagram illustrating implementation of a nonvolatile sequential machine according to another specific embodiment of the present invention.

FIG. 38 is a block diagram of a SpinRAM block for use with various embodiments of the invention.

### DETAILED DESCRIPTION OF SPECIFIC EMBODIMENTS

Reference will now be made in detail to specific embodiments of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims. In the following description, specific details are set forth in order to provide a thorough understanding of the present invention. The present invention may be practiced without some or all of these specific details. In addition, well known features may not have been described in detail to avoid unnecessarily obscuring the invention.

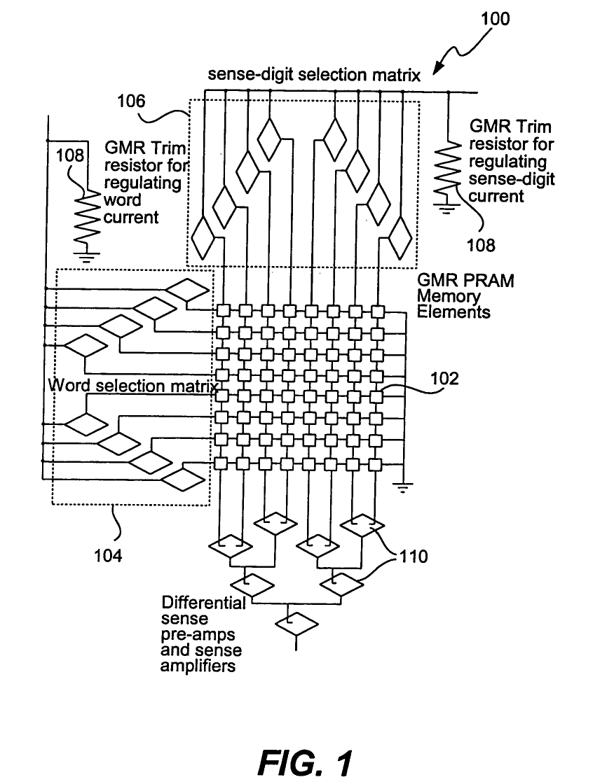

FIG. 1 is a simplified diagram of an all-metal random access memory 100, also referred to herein as a SpinRAM. As used herein, the term “all-metal” refers to structures which do not include semiconductor materials but which may include non-metallic insulating materials. And as will be discussed, SpinRAM and the various memory cell configurations described herein may be used with various embodiments of the present invention. It should be understood, however, that the descriptions of SpinRAM and memory cells are merely exemplary, and that other memory configurations and memory cell types may be employed without departing from the invention. For the sake of clarity, only 64 storage cells 102 have been shown. It will be understood, however, that the simplified architecture of FIG. 1 may be generalized to any size memory array desired. It should also be noted that the control lines for the selection electronics have been omitted for the same purpose.

Examples of storage cells for use with the present invention are described in U.S. Pat. No. 5,587,943 for NONVOLATILE MAGNETORESISTIVE MEMORY WITH FULLY CLOSED FLUX OPERATION issued on Dec. 24, 1996, and in U.S. Pat. No. 6,594,175 for HIGH DENSITY GIANT MAGNETORESISTIVE MEMORY CELL issued on Jul. 15, 2003, both of which are incorporated herein by reference in their entireties for all purposes. Specific examples of such storage cells will be described below.

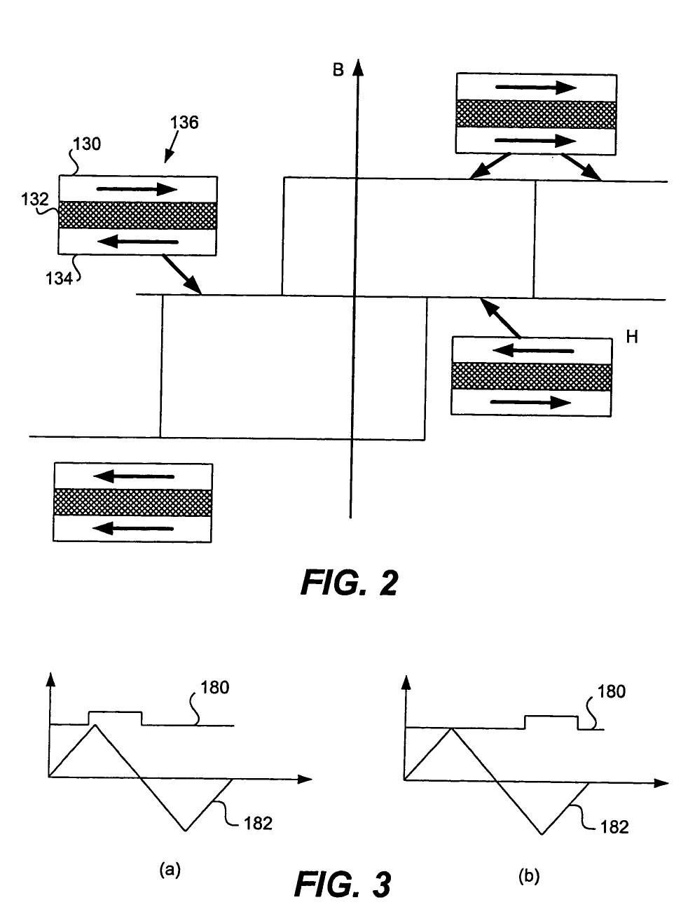

FIG. 2 shows the major hysteresis loop of a GMR exchange-coupled triple-layer film which may be used as a storage element according to specific embodiments of the present invention. Two magnetic layers 130 and 134 are separated by a nonmagnetic layer 132. The two magnetic layers have coercivities that differ by more than the exchange coupling between them such that layer 130 has a high coercivity (e.g., cobalt) and layer 134 has a low coercivity (e.g., permalloy). Film cross sections 136 show the magnetization at each part of the loop.

Beginning at the upper right quadrant, both top and bottom layers 130 and 134 are saturated in the same direction. If the applied field H is reduced to substantially zero and then reversed in direction, the layer having the lower coercivity switches first, as shown by the cross section in the upper left quadrant. The switching occurs when the field is equal to the sum of the coercivity of the lower coercivity film plus the coupling field.

As the applied field H is increased in the negative direction, the film layer having a higher coercivity switches directions, as depicted in the lower left quadrant. This switching occurs when the field magnitude is equal to the coercivity of the higher-coercivity film less the value of the exchange coupling. Thus, switching is carried out in such films in a two-step process.

Readout of the memory cell of FIG. 2 is achieved in a nondestructive fashion by measuring the resistance change in response to the change in the magnetization obtained by applying a field from a word line. The application of the field switches the lower-coercivity film. FIGS. 3(a) and 3(b) depict the resistive signals 180 when a triangular word current 182 is applied. FIG. 3(a) shows the signal corresponding to a “zero” state and FIG. 3(b) shows the signal corresponding to a “one” state.

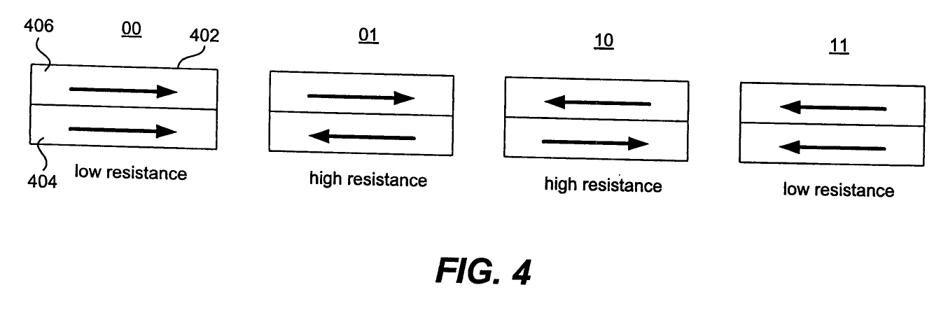

FIG. 4 shows four magnetization states of a memory cell 402 having a low coercivity storage layer 404 and a high coercivity storage layer 406. As indicated in the figure, each of the states represents a unique two-bit combination. That is, the state “00” is shown as both storage layers being magnetized to the right while the state “11” is shown as both layers being magnetized to the left. Because the magnetization vectors in this states are parallel, they exhibit relatively low resistance. By contrast, the states “01” and “10” are both characterized by the magnetization vectors oriented in opposite directions, i.e., a relatively high resistance state as compared to the parallel vectors due to the GMR effect.

Those of skill in the art will understand how each of the states may be written to memory cell 402. That is, layer 406 is magnetized first by the application of a magnetic field which overcomes the layer's coercivity. Because of its lower coercivity, layer 404 is also magnetized in the same direction, at least initially. The antiparallel state of layer 404 may then be written by application of a second magnetic field of the opposite orientation which is sufficient to overcome the coercivity of layer 404 but not layer 406.

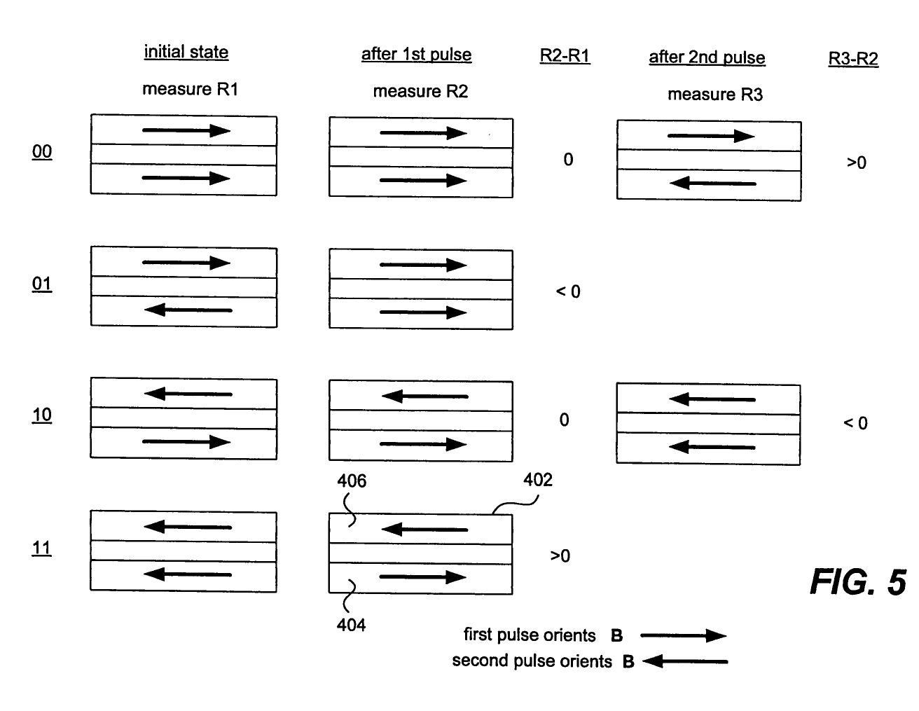

The reading of the information stored in memory cell 402 will now be described with reference to FIG. 5. As will be described, the read out process may vary depending upon the initial state of the cell. Initially, a resistance value R₁ associated with the multi-layer cell is measured while the cell is in an initial state (column 1). A magnetic field is then applied which is sufficient to overcome the coercivity of layer 404 and magnetize layer 404 in a particular direction, e.g., to the right as shown. A resistance value R₂ is then measured after the application of the magnetic field (column 2), and the difference between R₁ and R₂ determined (column 3). In the example shown, if R₂-R₁ is less than zero, then the initial state of the cell is determined to be the “01” state. Similarly, if R₂-R₁ is greater than zero, the initial state corresponds to the “11” state. The initial state is then rewritten to the cell.

If, on the other hand, there is no difference between R₁ and R₂, the initial state could have been either “00” or “10”. If all that is desired is to determine the state of the low coercivity layer 404, i.e., “0” in both instances, no further action need be taken. However, if the state of layer 406 must be determined, a second magnetic field may be applied in the direction opposite to the first magnetic field, e.g., to the left in this example, and a third resistance value R₃ measured (column 4). If R₃-R₂ is greater than zero, the initial state is determined to be “00”; if less than 0, the initial state is determined to be “10” (column 5). The initial state is then rewritten to the cell.

Although the descriptions of specific implementations refer to layers having different coercivities (e.g., layers 404 and 406), it should be noted that embodiments are contemplated which employ layers having the same coercivities, relying on alternative mechanisms to effect storage and readout. An example of such a mechanism is the use of localized fields to switch one layer without switching a nearby layer having the same coercivity. Examples of such embodiments are described below.

According to various other embodiments, memory cell designs are provided in which multiple bits of information may be stored in one memory cell. Specific embodiments will be described below in which 2, 3, or 4 bits of information may be stored in one memory cell and which employ either destructive read out (DRO) and nondestructive read out (NDRO). It will be understood, however, that particular ones of these designs may be generalized to store more bits of information than described.

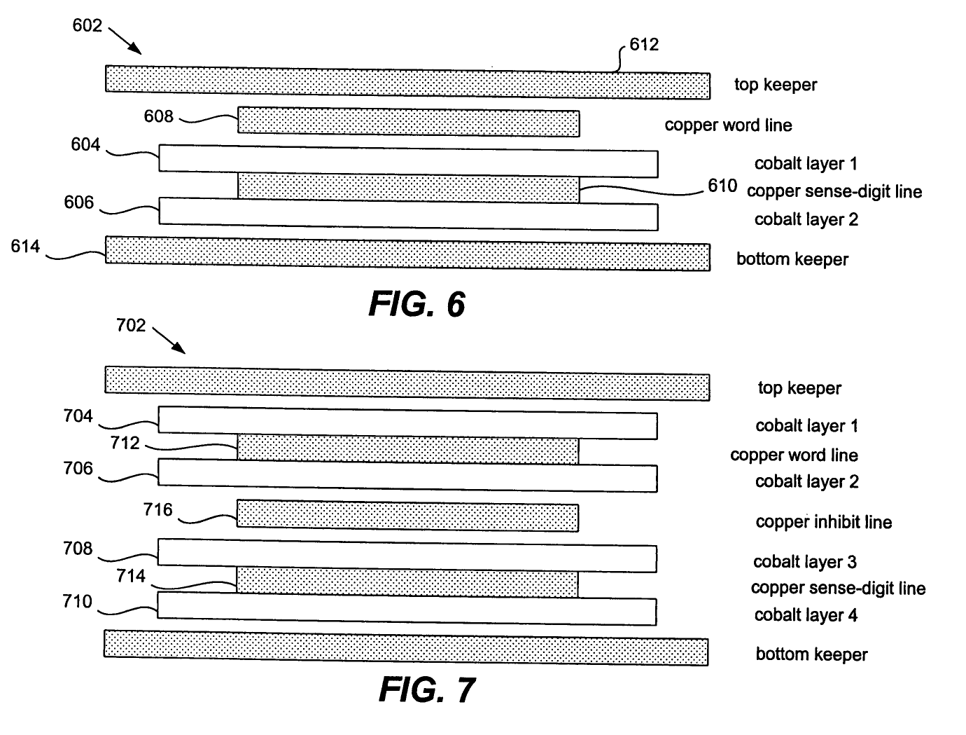

Three embodiments which employ DRO will now be described with reference to FIGS. 6 and 7. Each of the described embodiments employs cobalt storage layers, copper access lines, and a double keeper. However, it will be understood that a variety of materials may be employed for various ones of these elements without departing from the scope of the invention.

FIG. 6 shows a memory cell 602 configured to store two bits of information. Cobalt layers 604 and 606 are provided in which the individual bits of information are to be stored as represented by the magnetization vector associated with each. According to a specific embodiment, the coercivities of layers 604 and 606 are substantially equal. A copper word line 608 and a combined copper sense-digit line 610 are provided to provide read and write access to cell 602. Top and bottom keepers 612 and 614 are provided to ensure that memory cell 602 is a substantially closed flux structure. Such a double keeper configuration cancels any demagnetizing field from a magnetic film but does not impede the field from a strip line.

It should be noted that insulation layers are represented by the blank spaces between the layers shown. These layers were omitted for purpose of clarity. In addition, the various layers are shown having different widths for illustrative purposes. However, the layers of actual embodiments are typically the same width. Finally, it will be understood that the vertical dimension of the figures of the application are often exaggerated for illustrative purposes.

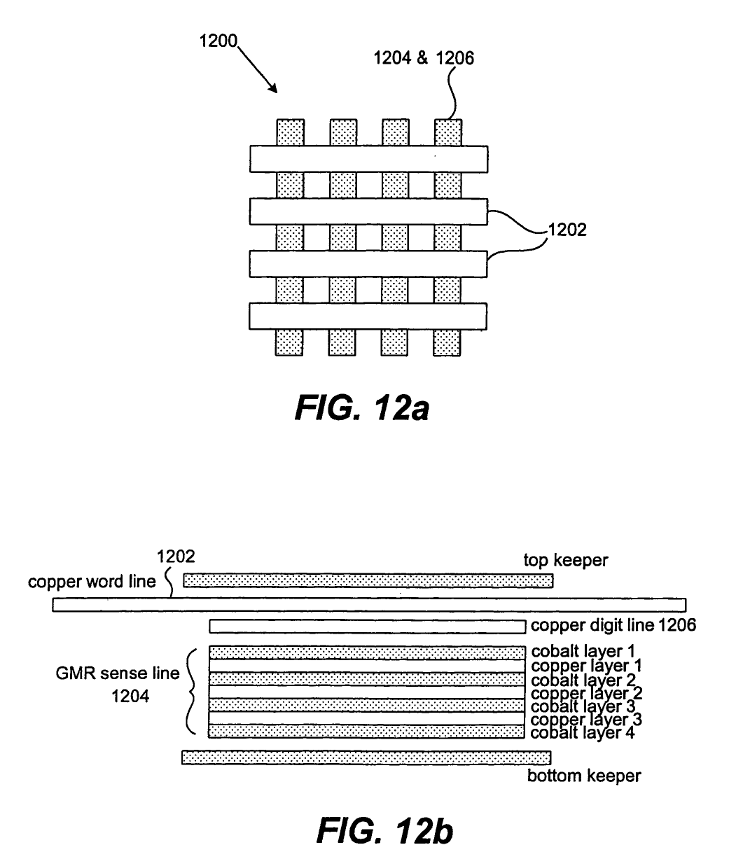

A memory module based on the memory cell of FIG. 6 may be similar to a memory module based on the single-bit memory cell of U.S. Pat. No. 5,587,943 incorporated by reference above. That is, such a memory module may have serpentine word lines generally oriented in the x-direction and sense-digit lines generally oriented in the y-direction as shown, for example, in FIG. 11. In such embodiments, the word and sense-digit lines run in the same direction at each bit location. Selection matrices are provided for selecting the word and sense-digit lines as well as low level gates and sense amps for the sense-digit lines. According to other embodiments, memory cells and modules are designed such that the word lines are straight and orthogonal to separate sense and digit lines as shown, for example, in FIGS. 12(a) and 12(b).

One can understand how to write to the dibit memory cell 602 of FIG. 6 by application of the right hand rule. That is, when the current in word line 608 is parallel to that in sense-digit line 610 and the amplitudes are equal, the field between these lines is zero, i.e., cobalt layer 604 experiences no applied field. However, the field experienced by cobalt layer 606 is the sum of the field contributions from the two lines. Thus, cobalt layer 606 may be written using coincident currents of the same polarity in lines 608 and 610, each of which may generate a field which by itself could not overcome the coercivity of layer 606 (i.e., less than H_{C}), but which, when combined with the field from the other line is sufficient to impose a magnetization on layer 606 (i.e., greater than H_{C}).

When, on the other hand, the current in word line 608 is antiparallel to that in sense-digit line 610 and the amplitudes of the currents are substantially equal, the combined field outside of lines 608 and 610 is effectively zero while the field between the lines, i.e., the field experienced by cobalt layer 604, is doubled. Thus, cobalt layer 604 may be written using coincident currents in the word and sense-digit lines of opposite polarity, each of which may have a field less than H_{C} but whose combined sum is greater than H_{C}.

According to a specific embodiment, the procedure for reading dibit memory cell 602 involves several steps. Initially, the resistance of sense-digit line 610 is measured. A logic state, e.g., a “1”, is then written to cobalt layer 604 with coincident currents in access lines 608 and 610 as described above. The resistance of sense-digit line 610 is then measured again. If it has changed, it is determined that the initial state of layer 604, i.e., the bit of information originally stored in layer 604, is different than the current state, e.g., if the layer was written as a “1” it must have previously been a “0”. If the resistance has not changed, the opposite conclusion is established, i.e., that the bit of information originally stored in layer 604 is the same as in the current state.

The state of layer 606 may subsequently be determined by reversing the state of layer 604 and comparing the resulting resistance to the last resistance measurement. The state of layer 606 may then be determined from whether the resistance increases or decreases. For example, if the top layer is switched from a “1” to a “0” and the resistance decreases, the bottom layer must be a “0”, i.e., the magnetization vectors of the two layers are now aligned. By contrast, if in such a scenario the resistance increased after such a switch, the bottom layer must be a “1”, i.e., the magnetization vectors of the two layers are now antiparallel. After a read operation, the original states of layers 604 and 606 may be rewritten as required.

Of course, it will be understood that a read operation may be performed to determine the state of both of the storage layers as described above, or to determine the state of either of the layers separately.

It will be understood that variations on the structure of memory cell 602 (as well as others of the memory cells described herein) may be made without departing from the scope of the present invention. For example, the respective coercivities or compositions of storage layers 604 and 606 may be varied. In addition, the current amplitudes of the current used to access memory cell 602 need not necessarily be equal to enable operation according to the principles of the present invention.

FIG. 7 shows a memory cell 702 which may be configured to store three or four bits of information. As with memory cell 602 of FIG. 6, insulating layers in the gaps between layers are not shown and the vertical dimension is exaggerated for clarity. In addition, in an actual embodiment, the films and access lines would likely be the same width but are differentiated here for illustrative purposes.

Memory cell 702 has four cobalt storage layers 704, 706, 708 and 710 each of which is capable of storing one bit of information. The cell access lines include a copper word line 712, a copper sense-digit line 714, and a copper inhibit line 716. The term “inhibit line” is used in reference to the inhibit line of the old ferrite core memories which employed three wires per cell. According to one implementation, an inhibit line allows a 3:1 ratio of field at selected to unselected locations, which is larger than the 2:1 ratio when there is no inhibit line. According to some embodiments, the inhibit line links all of the bits in an array. According to other embodiments, the inhibit line does not link all bits in the array. Rather they are configured to run diagonally through the array and are furnished with their own selection matrix.

As will become apparent, in three-bit embodiments, the magnetization states of storage layers 704 and 710 (and thus the information stored therein) are not independent. That is, each is magnetized in the opposite direction of the other. According to other embodiments (discussed below), this symmetry can be broken using a variety of techniques such that each of the four storage layers may be written and read independently.

According to the three-bit embodiment, the storage layers of memory cell 702 are characterized by substantially equal coercivities and may be written by the application of different combinations of coincident currents in the three access lines. The fields generated as a result of the applied currents are given by:
H₁=k{−I_{w}−Iᵢ−I_{d}} (1)
H₂=k{I_{w}−Iᵢ−I_{d}} (2)
H₃=k{I_{w}+Iᵢ−I_{d}} (3)
H₄=k{I_{w}+Iᵢ+I_{d}} (4)
where I_{w}, Iᵢ, and I_{d} correspond to the currents in the word, inhibit, and sense-digit lines, respectively, H₁-H₄ are the fields in layer 704-710, respectively, and k is a constant of proportionality inversely proportional to the line width and equal to 2π Oe per ma for a 1 micron width.

From these equations, it can be seen that layers 706 and 708 may each be switched with a current pulse combination that will not switch any other film in the cell. For example, if I_{w}=+H_{c}/3k and Iᵢ=I_{d}=−H_{c}/3k, then the field at layer 706 is H_{c}, while the field at layers 704 and 708 is H_{c}/3 and the field at layer 710 is −H_{c}/3. That is, there is a three-to-one ratio between the field at the desired storage layer and each of the other storage layers. It can also be seen, however, that in this particular embodiment where the coercivities of layers 704 and 710 are substantially equal, these layers do not switch independently. That is, a field combination that switches one of these two layers will switch the other in the opposite direction. Thus, in such an embodiment where layers 704 and 710 are interdependent in this way, only three bits of information may be stored in or retrieved from memory cell 702.

To effect reading of the information in three-bit memory cell 702, the control electronics for word line 712 and sense-digit line 714 are the same. That is, low-level gates and pre-amps are situated at the ends of each making the word lines, in effect, word-sense lines. The reading of an individual cobalt storage film is achieved in much the same way as described above with regard to dibit memory cell 602. That is, the resistance of the access line to which the storage film of interest is attached is measured. A logic state is then written to the storage film of interest and the resistance of the associated access line measured again. If the resistance changes, the storage film was originally in the opposite state of the logic state that was just written. If the resistance does not change, then the current logic state is the same as the original logic state. Also as described above with reference to dibit memory cell 602, the state of the other storage film associated with the same access line may be determined by switching the first film again and determining whether the resistance goes up or down.

According to various implementations, memory cell 702 is modified such that all four storage layers may be used to store independent bits of information. That is, memory cell 702 has enough storage layers to store four bits of information. However, as discussed above, if the coercivities of the layers are substantially equal, any current pulse sequence which writes storage layer 704 to a particular logic state will also write storage layer 710 to the opposite state.

According to a first embodiment, memory cell 702 becomes a four-bit memory cell with the addition of another access line (placed, for example, above cobalt layer 1) to break the symmetry which results in the interdependency of layers 704 and 710. This embodiment requires an additional masking level and an additional selection matrix to control the added access lines.

According to a second embodiment, the compositions of storage layers 704 and 710 are made sufficiently different such that their switching thresholds require different field strengths for switching. This may be accomplished, for example, by depositing a permalloy layer directly over the cobalt film of storage layer 704. This will give layer 704 a lower coercivity than layer 710. Thus, when coincident currents are applied to the access lines, the resulting fields will write layer 704 before writing layer 710.

According to a third embodiment, the separation spacing between the keepers and the cobalt storage films is adjusted such that demagnetizing fields become significant enough to break the symmetry. This embodiment takes advantage of the fact that even a perfect keeper doesn't completely cancel the demagnetizing field of a finite size magnetic film spaced a nonzero distance from the keeper. Such a demagnetizing field increases strongly with the distance between the magnetic field and the keeper. This demagnetizing field can be used to break the symmetry and allow both layer 704 and layer 710 to be written to the same state. For example, if one wishes to write a “0” to both layers 704 and 710, a pulse combination may first be applied which writes a “1” to layer 704 and a “0” to layer 710. A “1” is then written into each of layers 706 and 708. This results in a demagnetizing field which tends to bias layers 704 and 710 toward the “0” state. Thus, when a subsequent pulse combination is applied which tends to write layer 704 in the “0” state and layer 710 in the “1” state, only layer 710 is switched. This leaves both layers 704 and 710 in the same state, e.g., “0”. Layers 706 and 708 may then be written independently.

According to a fourth embodiment, a keeper layer replaces a portion of the center of line 716. This shields layers 704, 712 and 706 from the field generated by currents in layer 708, 714 and 710, and vice versa. This removes the redundancy and allows four bits of information to be independently stored.

The four-bit embodiment of memory cell 702 may be read in much the same way as the three-bit embodiment described above. According to a specific embodiment, this may be done by switching only the interior bits (i.e., layers 706 and 708) and using the read procedure described with reference to the dibit memory cell 602 of FIG. 6.

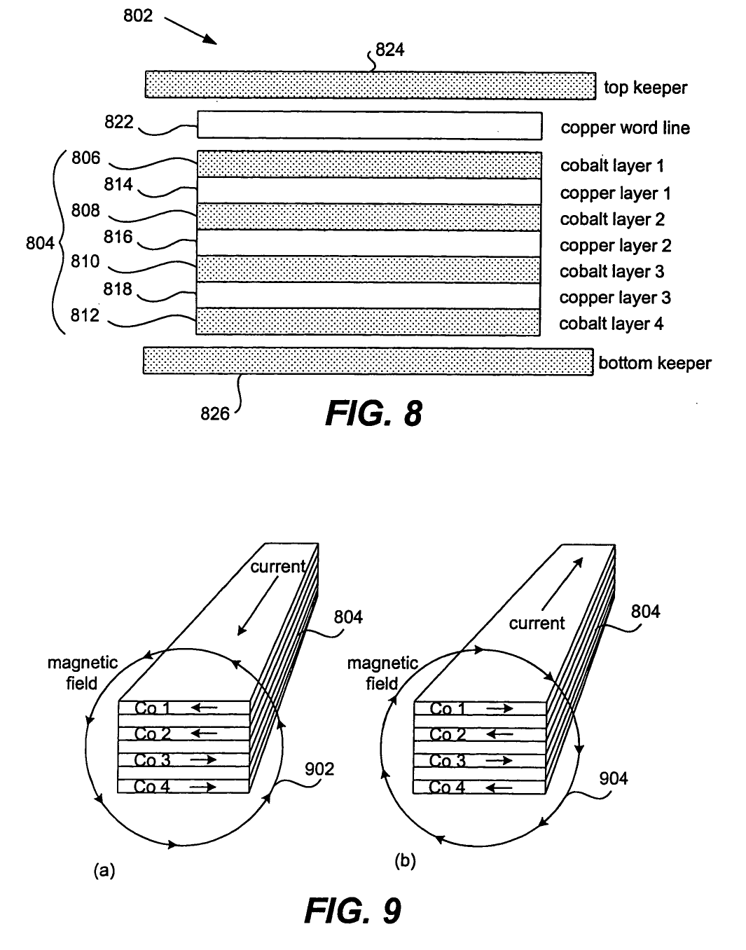

According to further embodiments, multi-layer memory cells are stacked to achieve increased information storage density. A double-density stacked memory cell 802 designed according to one such embodiment is shown in FIG. 8. According to various embodiments, this structure may be employed for 2-bit NDRO or 4-bit DRO. Memory cell 802 includes a GMR film structure 804 which functions as the sense-digit line of the cell. According to the specific embodiment shown, structure 804 is a multi-layer GMR structure having four cobalt layers 806, 808, 810, and 812, separated by three copper layers 814, 816, and 818. The cell also includes a copper word line 822 and top and bottom keepers 824 and 826. The purpose of the double keeper is to cancel the demagnetizing fields from the magnetic films while not impeding the fields from the access lines. For illustrative purposes, insulating layers located in the blank spaces between noncontiguous layers are not shown and the vertical dimension of the cell is exaggerated.

The reading and writing of memory cell 802 will now be described with reference to the FIGS. 9(a) and 9(b) which show the resulting magnetic fields from opposing currents in multi-layer GMR structure 804. Current flowing out of the page through GMR structure 804 generates a magnetic field 902 as shown in FIG. 9(a). The field is oriented to the left in the top two cobalt storage layers 806 and 808 and to the right in the bottom two cobalt storage layers 810 and 812. As will be understood, magnetic field 902 is stronger at layers 806 and 812, weaker at layers 808 and 810, and zero at the center of the structure.

In FIG. 9(b), the direction of the current is reversed, i.e., into the page, and reduced in magnitude such that the coercivities of the inner layers 808 and 810 are not overcome by magnetic field 904. This results in the switching of layers 806 and 812 but not layers 808 and 810 as shown. The result is that each cobalt film is magnetized antiparallel to its neighbor(s), a configuration which yields the highest magnetoresistance of sense-digit line 804.

Because the conductivity of copper is much larger than that of cobalt, the approximation that all of the current in sense-digit line 804 is carried by the copper layers may be made. Using this approximation, it can be seen that the magnitudes of the fields in layers 806 and 812 are approximately three times the magnitudes of the fields in layers 808 and 810. For example, the field experienced by cobalt layer 808 from copper layer 814 is cancelled by the field from copper layer 816, leaving only the field component from copper layer 818. By contrast, cobalt layer 806 experiences positive field contributions from each of the copper layers. This difference in field magnitude is the basis for operating the stacked memory cells.

An exemplary technique for writing of the dibit memory cell 802 will now be described with reference to FIGS. 8 and 9. According to this embodiment, the two inner cobalt layers 808 and 810 are used to store the information, and the two outside cobalt layers 806 and 812 are used to read out the information nondestructively, i.e., NDRO. The memory cell is written with a coincidence of currents in word line 822 and sense-digit line/GMR structure 804. Because, as discussed above, a current in sense-digit line 804 results in a much larger field at the outer cobalt layers than at the inner cobalt layers, it is possible to switch the outer layers without disturbing the inner ones.

A current in sense-digit line 804 will result in a magnetic field in cobalt layer 808 which is equal and opposite to the field experienced by cobalt layer 810. When a coincident current is applied to word line 822, the resulting field will add to the field in one of layers 808 and 810 and subtract from the other. This makes it possible to write to either one of layers 808 or 810 without disturbing the other. So, for example, to write to layer 810, a current which produces a field of magnitude H_{C}/2 at layer 810 is applied to sense-digit line 804 in the direction out of the page (see FIG. 9). A current one-third as large is coincidentally applied to word line 822 in the same direction resulting in another field of magnitude H_{C}/2 at layer 810. The combined field has a magnitude H_{C} which is sufficient to switch layer 810. However, because the first field contribution at layer 808 is −H_{C}/2, the two fields cancel and layer 808 does not switch.

To read the information stored in dibit memory cell 802 the magnitude of the read current in sense-digit line is ⅓ of that of the write current. This results in a field of H_{C}/2 at layer 806 and −H_{C}/2 at layer 812. The resulting fields at layers 808 and 810 are of magnitude H_{C}/6 and will therefore not cause any switching of these layers. To read the information in layer 808, layer 806 is written, i.e., magnetized, in a first direction and the resistance of sense-digit line 804 is measured. Layer 806 is then written in the other direction and the resistance measured again. The two resistance measurements are then compared. The resistance will be lower when layers 806 and 808 are magnetized in the same direction, and higher when they are magnetized in opposite directions. Therefore, the direction of magnetization of layer 808, i.e., the logic state stored in layer 808, may be determined from the comparison of the resistance values. The reading of layer 810 is achieved using the same procedure with layer 812.

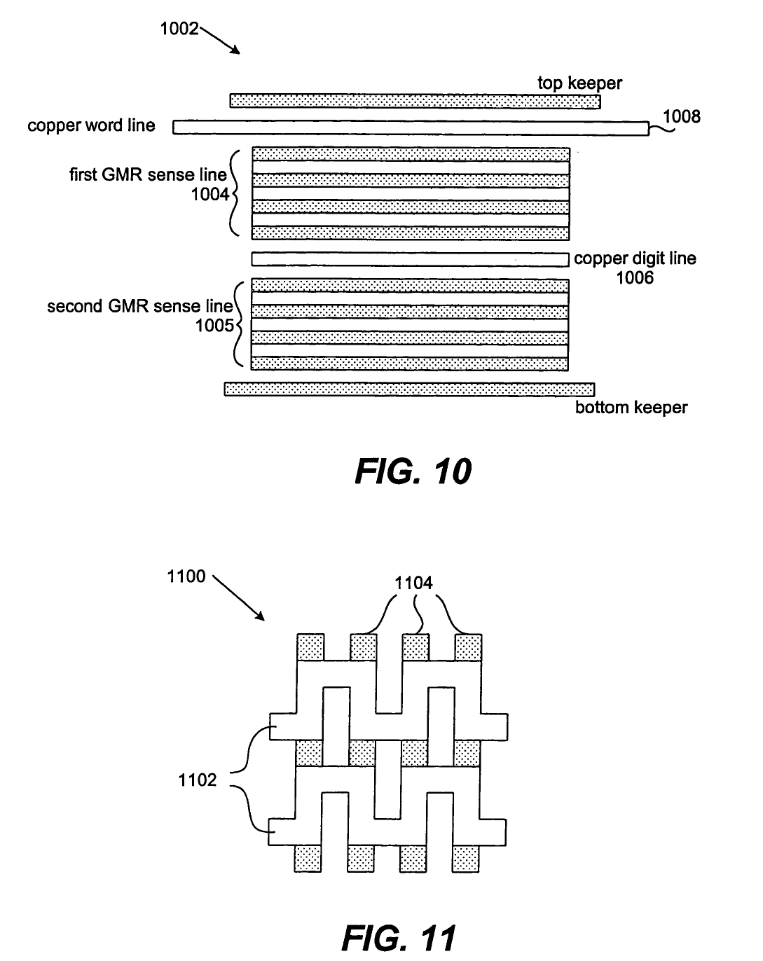

A quadruple-density stacked memory cell 1002 designed according to another embodiment is shown in FIG. 10. Memory cell 1002 includes two GMR film structures 1004 and 1005 which function as sense lines of the cell. According to a specific embodiment, each of structures 1004 and 1005 is designed similarly to the GMR film structure 804 shown in FIGS. 8, 9(a) and 9(b). That is, the embodiment shown in FIG. 10 stacks two of the single GMR structure of dibit memory cell 802 of FIG. 8 to effect storage of 4 bits of information NDRO or 8 bits DRO.

As with dibit cell 802, the four bits of information of quadbit cell 1002 are stored in the two center cobalt layers of each of sense lines 1004 and 1005. The fields on the top and bottom data bit layers of sense line 1004 will be denoted H₁ and H₂, respectively. The fields on the top and bottom data bit layers of sense line 1005 will be denoted H₃ and H₄, respectively. The term k will be used to represent the constant of proportionality between the magnetic field and current on the surface of a stripline having the width of those in the memory (k=2π Oe/ma for a line 1 micron wide, and is inversely proportional to the width of the stripline). The current in top sense line 1004 will be denoted i₁. The current in copper digit line 1006 will be denoted i₂. The current in bottom sense line 1005 will be denoted i₃. Using these definitions, the four fields at the four information storage layers are given by:
H₁=k(i₁/3+i₂+i₃) (5)
H₂=k(−i₁/3+i₂+i₃) (6)
H₃=k(−i₁−₂+i₃/3) (7)
H₄=k(−i₁−i₂−i₃/3) (8)
NDRO quadbit cell 1002 has the same control electronics for each of its two sense lines 1004 and 1005 as sense-digit line 804 of dibit cell 802, i.e., low level gates and preamps. From equations 5-8, it can be seen that each of the four information storage layers of quadbit cell 1002 may be written independently of the others by the appropriate combination of coincident current pulses in sense lines 1004 and 1005, digit line 1006 and word line 1008.

The read and write techniques described above with reference to dibit memory cell 802 of FIG. 8 may also be used to read the information stored in NDRO quadbit memory cell 1002. So, for example, a read would begin with measurement of the resistance of the sense line of which the storage layer of interest is a part. A particular logic state, e.g., a “1”, is then written to the outside cobalt layer nearest the storage layer of interest, i.e., the outside layer is magnetized in a specific direction. The resistance of the sense line is then measured and compared to the resistance prior to the first pulse. If there is a change in resistance, the bit value of the inner storage layer is determined from a comparison of the two resistance measurements. That is, if a “1” was written to the outside layer and a positive change in the resistance of the sense lines is measured, then the inner layer is storing a “0”, i.e., magnetized antiparallel to the outer layer; if a negative resistance change is measured, then the inner layer is storing a “1”. On the other hand, if there is no change after the first pulse, then the opposite logic state, e.g. a “0”, is written to the outside film, the resistance of the sense line is again measured, and the bit value is determined from a comparison of the three resistance measurements. That is, if the resistance change after the second pulse is positive, the inner layer is a “1”, i.e., magnetized parallel to the outer layer; if the resistance change is negative, the inner layer is a “0”. See FIG. 5. Note that this procedure can be used to read out all eight bits of a DRO 8-bit cell. If cell 1002 is used as an 8-bit DRO nonvolatile cell, the center copper digit line 1006 should be replaced by three layers, the top and bottom made of copper and the center a permalloy keeper.

According to a specific embodiment, all-metal memory cells may be configured into a memory array 1100 as shown in FIG. 11. The memory cells of the array are situated where serpentine word lines 1102 coincide with the vertical access lines 1104 which may comprise, for example, multi-layer sense-digit lines as in dibit cell 802, or separate sense and digit lines as in quadbit cell 1002.

According to other embodiments, the bit density of the dibit and quadbit memory cells may be further doubled by changing the shape of the word lines in an array 1100 of such devices and using separate sense and digit lines. This may be understood with reference to FIGS. 12(a) and 12(b). According to such embodiments word lines 1202 are straight and orthogonal to separate sense and digit lines (1204 and 1206, respectively). FIG. 12(b) shows a dibit cell embodiment. However, it will be understood that the same principle may be applied to a quadbit cell embodiment.

As can readily be seen by comparing the array design of FIGS. 11 and 12(a), the spacing between the word lines in array 1200 is decreased by a factor of two as compared to array 1100 with an attendant twofold increase in bit density. It should be noted that although the field from the word lines in array 1200 is perpendicular to the film easy axis, this field lowers the switching threshold of the cells beneath it with the result that only the portions of the magnetic films under an activated word line get switched. This enables one to switch one and only one bit in a given sense line.

Referring back to FIG. 1, the support electronics which provide random access to each of memory cells 102 are implemented with the GMR-based device referred to herein as a “transpinnor.” A transpinnor is a multifunctional, active GMR device with characteristics similar to both transistors and transformers. Like a transistor, it can be used for amplification, logic, or switching. Like a transformer, the transpinnor can be used to step voltages and currents up or down, with the input resistively isolated from the output. Like a transistor, a transpinnor can be integrated in a small space. Unlike conventional transformers, a transpinnor has no low frequency cutoff, the coupling being flat down to and including DC. In addition, the operational characteristics of the transpinnor (including amplification, current requirements, and speed) tend to improve as its dimensions get smaller. For more information on transpinnors, please refer to U.S. Pat. Nos. 5,929,636 and 6,031,273 for ALL-METAL, GIANT MAGNETORESISTIVE, SOLID-STATE COMPONENT, the entire disclosures of which are incorporated herein by reference for all purposes.

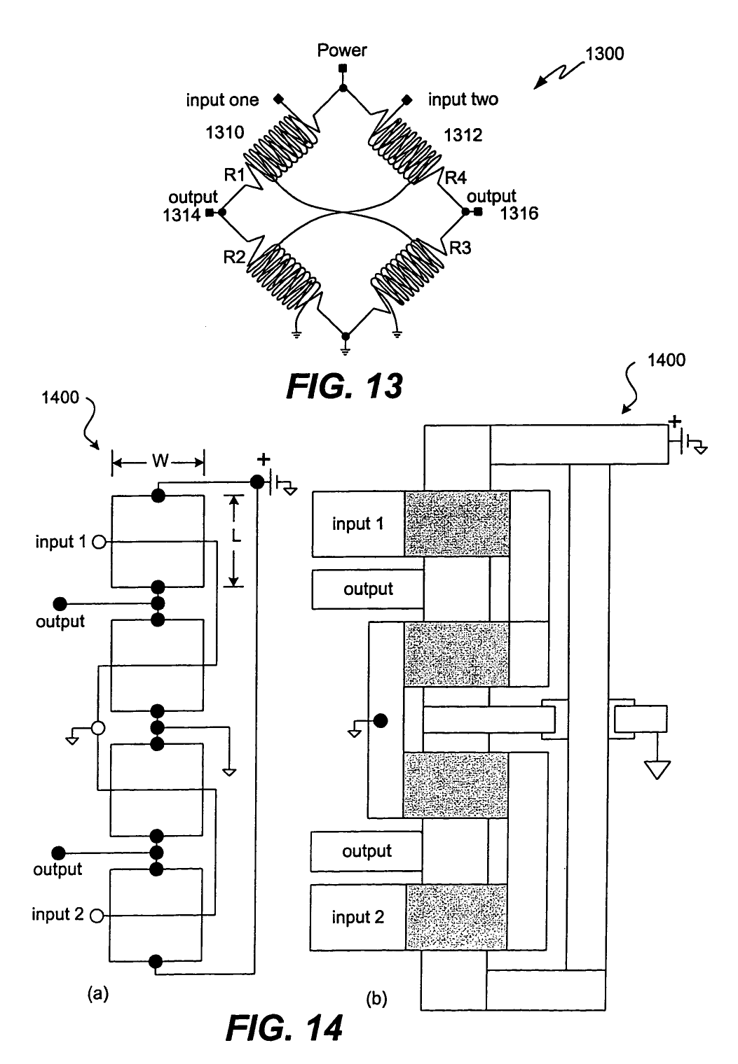

A specific implementation of a transpinnor 1300 is shown in FIG. 13. Four resistive elements R₁-R₄ comprising GMR film structures are configured as a Wheatstone bridge. Current in either of input lines 1310 or 1312 creates a magnetic field of one or more of GMR films R₁-R₄. This unbalances the bridge and creates an output signal between output terminals 1314 and 1316. In the transpinnor implementation of FIG. 13 input lines 1310 and 1312 are shown inductively coupled to resistive elements R₁-R₄ with coils. According to other integrated circuit embodiments, this coupling is achieved using striplines.

As mentioned above, the resistance of each leg of transpinnor 1300 may be changed by application of a magnetic field to manipulate the magnetization vectors of the respective GMR film's layers. Such fields are generated by the application of currents in input lines 1310 and 1312 which are electrically insulated from the GMR films. Input line 1310 is coupled to and provides magnetic fields for altering the resistance of GMR films R₁ and R₃. Input line 1312 is coupled inductively to and provides magnetic fields for altering the resistance of GMR films R₂ and R₄. If the resistances of all four GMR films are identical, equal currents in input lines 1310 and 1312 change the resistances equally and do not unbalance the bridge, thus resulting in zero output. If, however, unequal currents are applied, an imbalance results, thus resulting in a nonzero output.

FIG. 14 shows a circuit diagram (a) and an integrated circuit layout (b) of an integrated circuit implementation of a differential transpinnor 1400 for use with specific implementations.

The relationship between the output voltage of transpinnor 1300 and a variety of other parameters including power supply voltage, input current, GMR value, leg resistance values, and output resistance will now be described. This analysis assumes the ideal case where the resistance of each of four resistive elements R₁-R₄ (when in identical magnetic states) is identical, and denotes this resistance value as r. When a positive current is applied at input 1 and a negative current is applied at input 2, the various resistances are given by:
R₁=r(1−δ) (9a)
R₂=r(1+δ) (9b)
R₃=r(1−δ) (9c)
R₄=r(1+δ) (9d)
Where
δ=f(H) gmr/2 (10)
gmr is the decimal equivalent of GMR (i.e., gmr=GMR/100), and f(H) is a number less than or equal to one, representing the fraction that a layer has switched.

The output resistance of transpinnor 1300 is denoted r₅. The current in each of resistive elements R₁-R₄ and r₅ denoted i₁-i₅, respectively. The voltage drop across the entire bridge, i.e., the voltage applied to the power lead) is denoted V. From Kirchoff's laws we then have
i₁−i₂−i₅=0 (11a)
i₄−i₃+i₅=0 (11b)
and from symmetry,
i=i₃ (12a)
i₂=i₄ (12b)
Because the voltage drop over any path between the power lead and ground must be V,
(1−δ)riᵢ+(1+δ)ri₂=V (13)
(1−δ)ri+i₅r₅+(1−δ)ri₁=V (14)

Combining equations (11), (13), and (14),
i₅=2i₁δ/[1+δ/(r₅/r)] (15a)
This equation represents the output current of transpinnor 1300.

Also of interest is the dependence of the amplification factor,
A=output current/input current (16)
on the power supply to transpinnor 1300 and the line width of the GMR films. For this analysis will use the approximation that r₅/r<<1. This is due to the fact that the input and output lines of transpinnor 1300 are much thicker than the GMR films (e.g., 20 run of copper and 300 nm of AlCu vs. 2-4 nm of copper). In addition, δ<<1 also (see equation 10). In the case of complete switching, equation 15a then becomes
i₅=2i₁δ=i₁gmr (15b)

The input current must be sufficient to switch the lower coercivity, e.g., permalloy layer of the GMR films, i.e., sufficient to produce a magnetic field equal to the layer coercivity, H_{C}. The field H produced by a current i in a stripline of width w and length L is found from Maxwell's equation, curl H=J′, to be
H=2πi/w Oe (17)
where i is in mA and w is in microns. (In changing units from Maxwell's equation to those in equation (17) it should be noted that 4πOe=10³ amps/meter.) Thus, the input current required to produce a field H_{C} is
input current=(½π)H_{c}w mA/(Oe-micron) (18)

To derive the output current, it should be noted with reference to FIG. 13 that the power voltage V is applied to R₁ and R₂ in series, and that because i₅ is small, the current in resistive elements R₁ and R₂ can be approximated as i₁. Thus, the current i₁, according to Ohm's law, is the ratio of V (in volts) to the sum of R₁ and R₂, or 2r (in ohms). So, i₁=10³ V/(2r) mA, and therefore according to equation (15b) the output current is
output current=10³ gmrV/(2r)mA (19)
The amplification factor is then
A=π1000 gmrV/(rH_{c}w) (20a)

It is further useful to write the resistance r as the sheet resistivity, R_{sq} (ohms per square) multiplied by the number of squares. The number of squares of one of the GMR resistive elements of FIG. 14 is L/w. Thus, the amplification may be written
A=π1000 gmr V/(H_{c}LR_{sq}) (20b)
where H_{C} is in Oe, and w and L are in microns.

As discussed above, transpinnors form the basis for the all-metal support electronics for memory 100 of FIG. 1. That is, transpinnors are used to select the word lines to be activated (104), select the sense-digit and reference lines to activated (106), regulate the voltage to the drive lines (108), amplify the difference in current between selected sense-digit and reference line pairs (110), and perform further sense amplification in successive stages.

It turns out that the transpinnor is extremely effective for applications in which a physical signal is to be read above an offset arising from the difference between two unevenly match input lines. It functions as a transformer at its input, rejecting the common-mode signal between the two lines, and as a differential amplifier at its output, amplifying the physical signal. In memory 100 there is a differential transpinnor 110 coupled to each sense-digit/reference line pair such that the sense-digit line is connected to input 1 of the transpinnor and the corresponding reference line is connected to input 2 (see FIGS. 13 and 14). As discussed above, inputs 1 and 2 of each transpinnor are only inductively coupled to its GMR film resistive elements, the input being DC isolated from the output.

When the sense-digit and reference lines of a pair are in the same magnetic state, the output of the differential transpinnor 110 should be zero. However, because of imperfections arising in the fabrication process, the resistance of a sense-digit line will typically be different than that of its reference line. Consequently, when the same voltage is applied to the two lines, different currents enter the two inputs of the associated differential transpinnor 110 causing a nonzero output, and thus the potential for error. According to a specific embodiment, the differential transpinnor 110 for each sense-digit/reference line pair may be trimmed to compensate for this imbalance.

That is, compensation for the resistive imbalance is achieved by reducing the output of the transpinnor through at least partial reversal of one of the high coercivity, i.e., cobalt, layer. According to a specific embodiment, the other side of the transpinnor is operated with the high coercivity layer(s) saturated. The low coercivity layer(s) remains free to react to the input current, thereby producing the dynamic output. By reversing just the right percentage of the cobalt layer, the output of the transpinnor can be made to go to zero when the reference and sense-digit lines are in the same magnetic state, i.e., when it is supposed to be zero.

Equation (15b) represents the case where the currents of inputs 1 and 2 are equal in magnitude and of opposite polarity. When the currents are of the same polarity and different magnitude, the equation becomes
i₅=i₁(δ₁−δ₂) (21)
Since the two fractional resistance changes are unequal, i₅ is nonzero. In equation (10), f(H) is the fraction of the film for which the magnetization of the high coercivity layer and the low coercivity layer (i.e., the cobalt layer and the permalloy layer) are antiparallel less that for which they are parallel. We can therefore write f(H) as the product of two terms, one representing the high coercivity layer and one representing the low coercivity layer,
f(H)=f_{c}(H)fₚ(H) (22)
where f_{c}(H) is the fraction of the cobalt layer magnetized in the positive direction less that magnetized in the negative direction and fₚ(H) is the corresponding fraction for the permalloy layer. This assumes that the layers switch independently of one another which is a reasonable assumption in that the coercivity of cobalt is much higher than that of the permalloy, and the transpinnor is typically operated at low field where only the magnetization of the permalloy changes and that of the cobalt remains fixed. That is,
f_{c}(H)=constant (23)
but the values of f_{c}(H) will in general be different for the two inputs.

The transpinnor can be set up so that the response of the permalloy to the applied field (from the current in the input line) is relatively linear for the current range of interest, i.e.,
fₚ=kI |fₚ<1 (24)
where the value of the proportionality constant k is determined by the shear of the loop. Denote the current from the reference line by i_{ref} and the current from the sense-digit line by iₛₑₙₛₑ. Then
δ₁=f_{c1}fₚ gmr/2=f_{c1}k iₛₑₙₛₑ gmr/2 (25)
δ₂=f_{c2}fₚ gmr/2=f_{c2}k i_{ref} gmr/2 (26)

Then, by equations (21), (25), and (26), the output current 15 of the transpinnor is given by
i₅=i₁(δ₁−δ₂)=i₁k(gmr/2)(f_{c1} iₛₑₙₛₑ−f_{c2}i_{ref}) (27)

Equation (27) reveals that even if the sense current is different than the reference current when the line are in the same magnetic state, the output current i₅ can be made zero by adjusting the magnetization in the cobalt film. Thus, for example, if the current in a sense-digit line is greater than that in the corresponding reference line, the currents can be balanced by saturating the cobalt in the reference leg of the transpinnor in the positive direction so that f_{c2}=1 and partially reversing the cobalt in the sense-digit leg of the transpinnor such that f_{c1}=i_{ref}/iₛₑₙₛₑ. This balances the input, even though the lines have different resistances. The adjustment is facilitated by the fact that the two cobalt layers can be adjusted independently. It should be noted that this technique can compensate for virtually any resistive inequality in a given sense-digit/reference line pair. This is even the case where the difference in resistance is much greater than the films' gmr values.

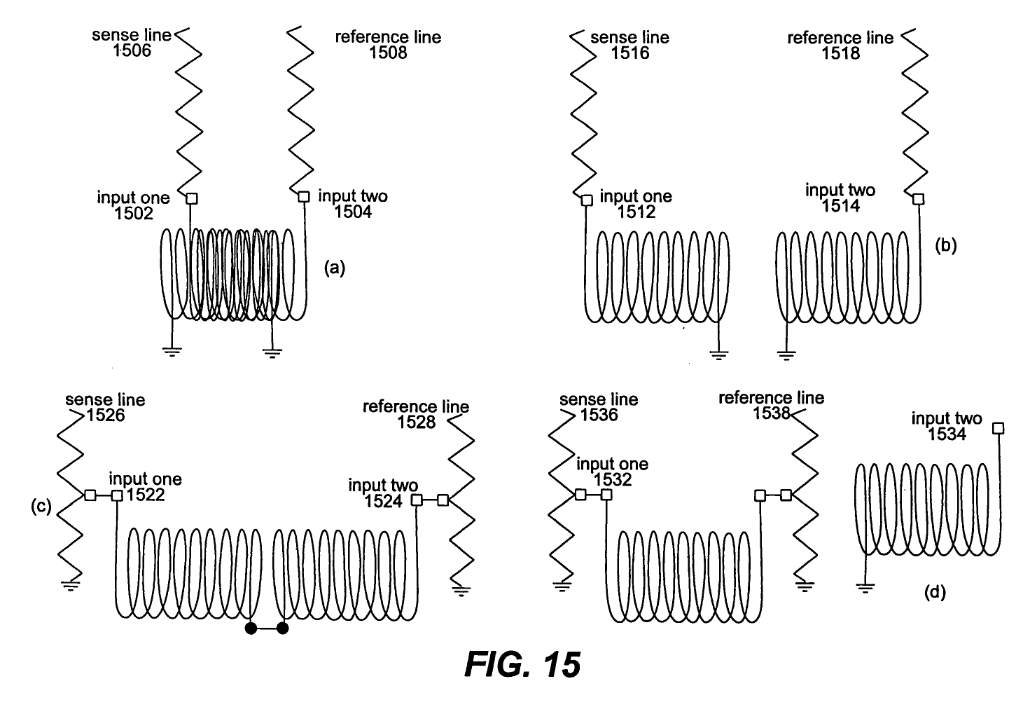

According to various specific embodiments of the present, there are a number of ways in which a transpinnor may be connected to a sense-digit/reference line pair. Four of these options will now be described with reference to FIG. 15. Each option is shown using coils. However, it will be understood that analogous embodiments using striplines are contemplated. In addition, for the purpose of clarity, each of the embodiments is shown with only the transpinnor's input lines, i.e., omitting the resistive elements.

FIG. 15(a) shows the input lines 1502 and 1504 of a transpinnor configured such that each of the transpinnor's four resistive elements (not shown) is influenced by current from both sense-digit line 1506 and reference line 1508. In the figure this is shown as the coils being configured concentrically with the coils slightly displaced from one another. In a stripline embodiment, the input lines would be striplines deposited on top of the other layers with insulation in between. This configuration has the highest sensitivity for differential amplification of the four shown, but has relatively low sensitivity for trimming unless the overlap of the input lines is only partial.

FIG. 15(b) shows input lines 1512 and 1514 of a transpinnor configured such that the current from sense-digit line 1516 goes through only input line 1512 which supplies magnetic fields to two of the transpinnor's resistive elements, while current from reference line 1518 goes through only input line 1514 which supplies magnetic fields to the other two resistive elements of the transpinnor. Transpinnor 1300 of FIG. 13, for example, is configured for such a connection.

FIG. 15(c) shows input lines 1522 and 1524 of a transpinnor connected in series between the midpoints of sense-digit line 1526 and reference line 1528. In this configuration, the current flowing through the two input lines is proportional to the difference in resistance between them.

FIG. 15(d) shows input line 1532 coupled between sense-digit line 1536 and reference line 1538. Input line 1534 is used to compensate for any intrinsic difference in resistance between them, i.e., to eliminate any offset. This configuration is the least sensitive of the four shown for differential amplification.

The four configurations of FIG. 15 lead to four different methods of using transpinnors for resistive trimming.

A differential transpinnor exhibits hysteresis unless operated in a specific way. This hysteresis can be avoided if the transpinnor is biased in the hard direction of the low coercivity (e.g., permalloy) layer with a field greater than or equal to the anisotropy field. This eliminates the hysteresis and the permeability becomes very large. The high coercivity (e.g., cobalt) layer is largely unaffected because its anisotropy field is typically much larger than that of the low coercivity layer. The signal field is applied by the input lines of the transpinnor and is in the easy-axis direction.

A second method which requires no bias field is to fabricate the transpinnor with the easy axis of the low coercivity layer perpendicular to the easy axis of the high coercivity layer. The low coercivity layer thus undergoes uniform magnetization rotation rather than wall-motion switching.

A third method of dealing with transpinnor hysteresis is to initialize the transpinnor the same way before each read operation. For example, each read operation could be started by the application of a negative pulse which switches all the low coercivity layers but not any of the high coercivity layers. This erases any previous low coercivity layer history.

According to a fourth method, the low coercivity layer of the transpinnor is initialized antiparallel to the high coercivity layer, leaving it on the very steep part of the device's hysteresis curve where a small input current will produce a large output.

According to a specific embodiment, when a transpinnor is used to balance a sense-digit line against its reference line, the resistive elements of the transpinnor are adjusted such that when the sense-digit and reference lines are in identical magnetic states (i.e., with the same number of ones and zeros in the storage layers of the two lines and at the corresponding locations in each, and with the same corresponding magnetizations in the readout layers of the two lines), the transpinnor gives zero output. When a bit is changed on the reference line but not the sense-digit line, the ratio of resistances changes and the transpinnor gives a nonzero output. That is, the transpinnor is adjusted to give zero output not when both input currents are equal, but when the sense-digit line and the reference line are in the same magnetic state. Note that the voltages applied to the two lines are equal, but because the resistances are unequal, the currents in the lines are unequal. Thus, though the supply to the line pair is a constant current, the individual currents in the pair may be different.

During a read operation, the read current through the trimming transpinnor is large enough to switch its low coercivity layer, but not its high coercivity layer. Therefore, the trimming adjustment is made to the high coercivity layer (which remains in the partially switched state during the read operation), not the low coercivity layer (which needs to be free to change in response to the read current). The high coercivity layer in the transpinnor is not affected by write operations because the resistive elements of the transpinnors are not physically connected to the sense-digit lines.

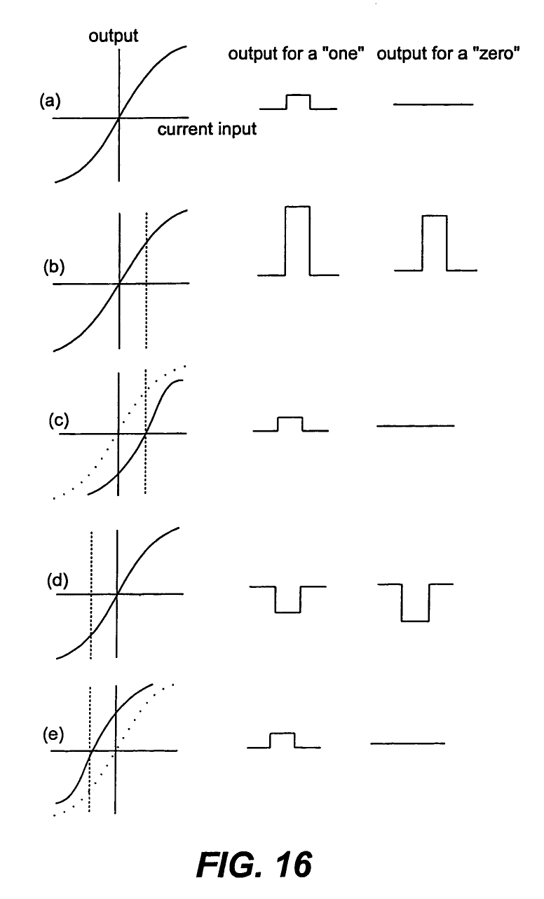

FIGS. 16(a)-16(e) illustrate the effect of the trimming technique on the balancing of sense-digit/reference line pairs according to a specific embodiment thereof. Each set of three diagrams corresponds to a transpinnor with specific characteristics. In each set the left most diagram represents the transpinnor output, the middle diagram the output from read signal for a “1,” and the right most diagram the output from a read signal for a “0.”

When the transpinnor associated with a particular sense-digit/reference line pair is well balanced, i.e., the sense-digit line and the reference line have equal resistances, the outputs for a “1” and a “0” are as shown in FIG. 16(a). When the resistance of the sense-digit line is smaller than that of the reference line, the result is an input current offset represented by the vertical dashed line in FIG. 16(b). The creates the “pedestal” of FIG. 16(b) as a result of which the output for a “0” can be mistaken for that of a “1.” If, however, a prep pulse of the appropriate magnitude is applied, the response curve of the transpinnor is shifted as shown in FIG. 16(c), as a result of which the pedestal of FIG. 16(b) is removed.

Similarly, if the resistance of the sense-digit line is greater than that of its corresponding reference line, the result is a pedestal of the opposite polarity as illustrated in FIG. 16(d). This pedestal may also be eliminated by the application of a prep pulse of the appropriate magnitude which moves the response curve of the transpinnor to the left as shown in FIG. 16(e).

It will be understood with reference to the diagrams of FIG. 16 that by properly balancing a transpinnor coupled to a sense-digit/reference line pair, the additional steps otherwise required for removing the read operation pedestal may be eliminated and the read time correspondingly reduced.

Referring once again to FIG. 1, three types of GMR structures are shown working together to create an operational all-metal random access memory or SpinRAM 100. As discussed above, memory cells 102 comprise multi-layer thin film elements each of which stores one or more bits of information. Word and sense-digit selection electronics (104 and 106) and amplifiers 110 comprise transpinnors. Trim resistors 108 are provided for regulating the current to the memory access lines and comprise GMR films the resistance of which may be trimmed by controlling the percentage switching of the films' high coercivity layers (as discussed above with regard to the balancing of a transpinnor).

According to specific embodiments, it is desirable that the GMR films for each of the SpinRAM memory elements 102 have high GMR values to achieve a favorable signal-to-noise ratio. Relatively low coercivities may also be desirable for both the high and low coercivity layers of the memory elements to ensure low switching currents, although the difference in coercivity between the high and low coercivity layers should be sufficiently large to maintain satisfactory operating margins.

The characteristics of the GMR films for the transpinnor-based elements (i.e., 104, 106, and 110) may be similar to those discussed above for the memory elements, but may differ in some respects. That is, like the memory elements, high GMR values are desirable, as is a relatively low coercivity for the low coercivity layers. However, the coercivity of the high coercivity layers can be significantly larger than that which would be acceptable for the corresponding layers of the memory elements. In addition, it is desirable that the GMR values and coercivities of the layers of GMR resistors 108 be relatively high to ensure stability.

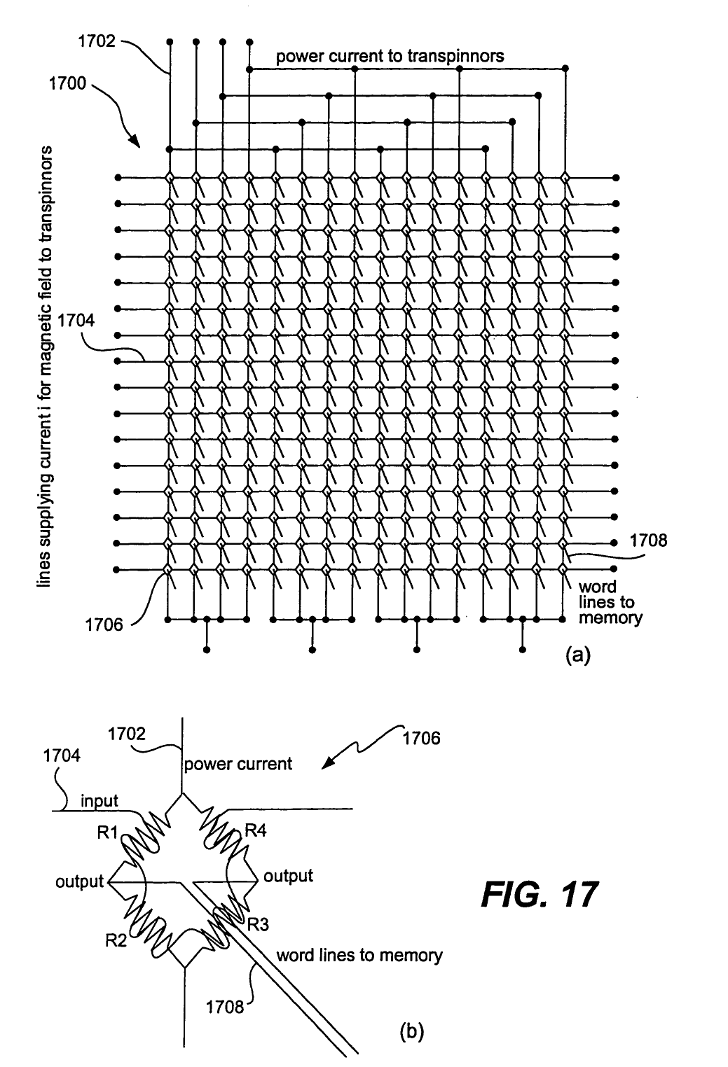

A simplified schematic of a transpinnor-based selection matrix is shown in FIG. 17. FIG. 17(a) shows a word line selection matrix 1700 the design for which, it will be understood, may also be used as a sense-digit line selection matrix. It will also be understood that although the embodiment shown selects from among 256 word lines, many variations of the size of the selection matrix remain within the scope of the invention.

At each intersection of a power current line 1702 and a transpinnor selection line 1704 is a transpinnor 1706 which delivers current to a selected word (or sense-digit) line 1708. A simplified representation of a transpinnor 1706 is shown in FIG. 17(b). The input selection line 1704 is shown coupled to the individual GMR resistive elements via a plurality of coils in FIG. 17(b) for didactic reasons. It will be understood, however, that the input selection line is fabricated as a stripline in integrated circuit embodiments. At the output of each transpinnor 1706 is one of 256 word (or sense-digit) lines 1708. According to a specific embodiment, the configuration of selection matrix 1700 is advantageous in that power need only be supplied to one column of transpinnors (i.e., the one corresponding to a selected word line) at one time. Transpinnors 1706 function as the gates of selection matrix 1700, a particular word or sense-digit line being selected in the following manner.

A power current is applied to the column of transpinnors 1706 which includes the transpinnor corresponding to the line 1708 to be selected via one of power current lines 1702. Power being applied to each resistively balanced transpinnor results in zero output. As discussed above, individual transpinnors may be balanced to achieve this zero output using the technique referred to herein as magnetoresistive trimming. Coincident with the application of the power current, a current is transmitted via the input selection line 1704 corresponding to the transpinnor 1706 to be selected. The field associated with this current unbalances the selected transpinnor by at least partially reversing the magnetization of at least one of the transpinnor's low coercivity layers, and thereby changing the resistance of the corresponding GMR element. The transpinnor imbalance results in a corresponding output current which is delivered to the memory array via the word (or sense-digit) line 1708 connected to the transpinnor output.

Most computer systems are based on the use of volatile main memory which is typically implemented using dynamic random access memory (DRAM) technology. The volatile nature of DRAM and its relatively high cost per bit of storage capacity has, in turn, led to the development of magnetic disk technology as the basis for the permanent mass storage component of computer memory systems. This hybrid architecture has some well know disadvantages which include, among other things, the relatively long access time for magnetic disks, increased operating system complexity, and the risk of data loss during power failures.

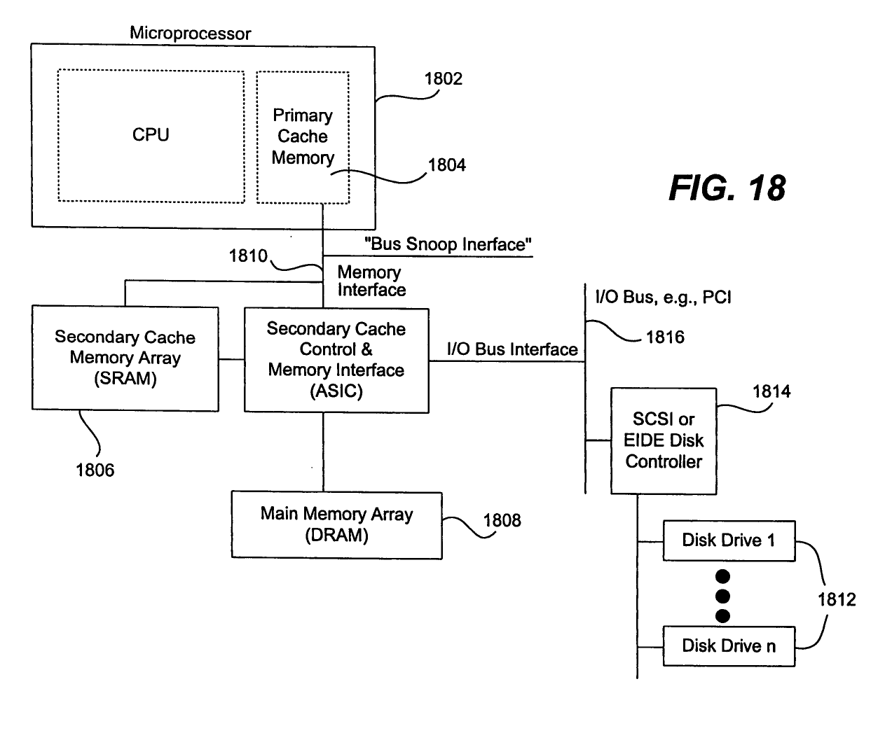

The block diagram of FIG. 18 shows a generalized computer memory hierarchy associated with a microprocessor 1802. Several types of memory technologies which serve a variety of functions are employed. A high performance primary cache 1804 is integrated with microprocessor 1802. A secondary cache 1806 is also provided. Cache memories are usually small (e.g., 256K), power hungry SRAM devices. They greatly enhance system performance by providing the microprocessor with a small block of information which may be accessed at speeds rivaling the speed of operation of the microprocessor itself. Storing a small block of data in cache memory allows most microprocessor requests (e.g., >90%) to be filled at SRAM speeds (e.g., 10 ns).

If a requested piece of information is not present in the cache, the information must be retrieved from main memory 1808. Main memory 1808 communicates with microprocessor 1802 via memory interface 1810, is typically much larger (e.g., 16M) and slower (e.g., access times of 70 ns) than cache memory, and is typically implemented in DRAM. This main memory provides microprocessor 1802 with relatively fast access to large blocks of data as well as stores and streams data to the display.

If a requested piece of information is not present in main memory, the information must be retrieved from mass storage. Such mass storage may be provided by one or more magnetic disks 1812 which are coupled to microprocessor 1802 via disk controller 1814 and I/O bus 1816 which may be, for example, an ISA, EISA, PCMCIA, PCI, or CompactPCI bus. The typical storage capacity of such magnetic disk technology is on the order of gigabytes, but the access times are orders of magnitude slower than the other levels of the memory hierarchy (e.g., 12 ms).

The technology described herein provides an architecture in which each of the memories outside of microprocessor 1802 may be implemented with the all-metal giant magnetoresistive memories described herein. These memories will also be referred to herein as SpinRAMs®. A comparison of the memory technologies described herein with the conventional memory technologies they replace is given in Table 1. The SpinRAM technology replacement for DRAM/FLASH is also referred to as SpinRAM2 and the replacement for rotating disk storage is referred to as SpinRAM3. SpinRAM1 is the replacement for SRAM such as that used in cache memories.

TABLE 1
Memory Technology Comparison

| | Technology | | | |
|---|---|---|---|---|
| | SpinRAM replacement for | | | |
| | (based on SPICE simulation) | | Conven- | Conven- |
| | DRAM/FLASH | Disk | tional | tional |
| Parameter | (SpinRAM2) | (SpinRAM3) | FLASH | DRAM |
| write time | 20 ns | 50 ns | 5-10 :s | 50-100 ns |
| read time | 60 ns | 1 :s | 70-150 ns | 30-70 ns |
| miniaturiza- | litho- | litho- | charge | charge |
| tion | graphy | graphy | leakage | leakage |
| limit | | | | |
| cycling | infinite | infinite | 10⁶ | Infinite |
| endurance | | | | |
| Average | low | low | medium | High |
| power | | | | |
| nonvolatility | yes | yes | yes | No |
| Random | yes | yes | no | Yes |
| access | | | | |
| intrinsic | yes | yes | no | No |
| radhardness | | | | |

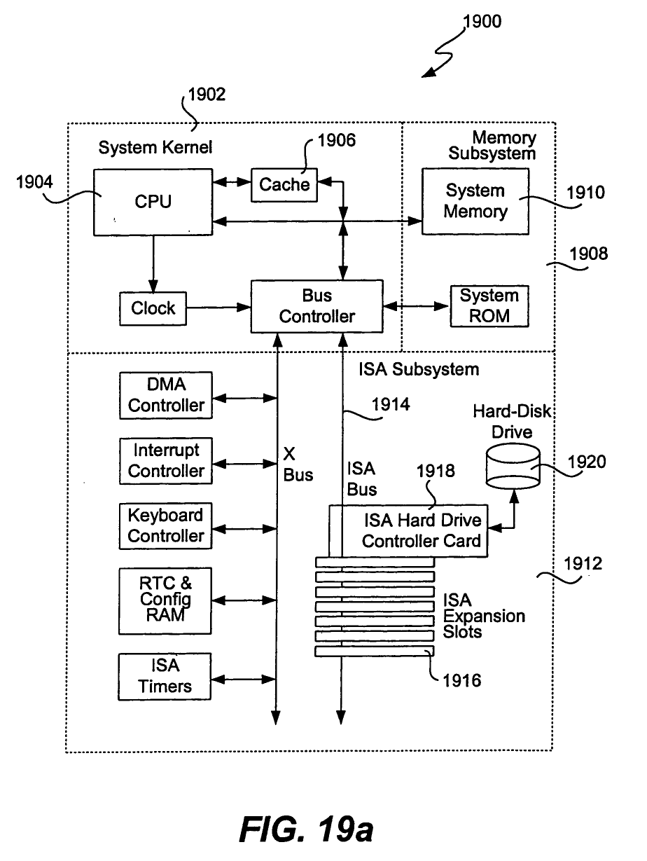

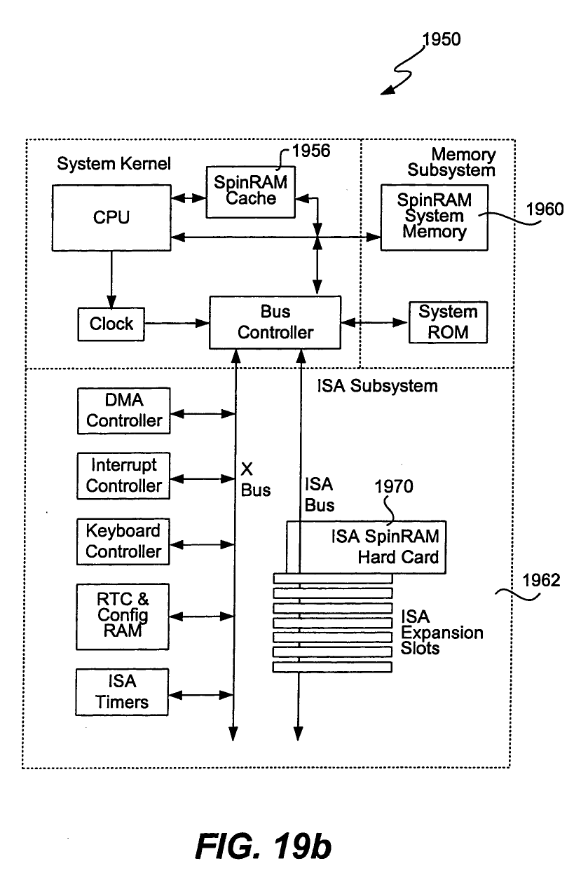

An example of a unified memory architecture will now be described with reference to FIGS. 19(a) and 19(b). FIG. 19(a) is a functional block diagram of an ISA-bus IBM compatible personal computer system 1900. System kernel 1902 includes CPU 1904 and cache memory 1906 which may be the CPU's primary cache or, where the CPU includes an integrated primary cache, the CPU's secondary cache. Memory subsystem 1908 includes the main system memory 1910. ISA subsystem 1912 includes an ISA bus 1914 along which are disposed ISA expansion slots 1916. At least one of the expansion slots is coupled to an ISA hard drive controller card 1918 which controls magnetic hard disk drive 1920.

FIG. 19(b) is a functional block diagram of an ISA-bus IBM compatible computer system 1950 having a memory architecture designed according to a specific embodiment in which the cache, system, and hard disk memories of computer system 1900 have been replaced with all-metal giant magnetoresistive memories. It will be understood that, although an ISA system is shown in this example, the same principles may be applied to virtually any computer system, e.g., EISA, PCI, CompactPCI, etc.

It should also be noted that, although all three of the cache, system and hard disk memories are replaced in this example, some other subset of these memories (e.g., just the disk drive and system memory) may be replaced by all-metal giant magnetoresistive memory technology.

With reference to ISA subsystem 1962, ISA SpinRAM hard card 1970 replaces the disk drive and controller of system 1900. The memory architecture of SpinRAM hard card 1970 may be, for example, any of the architectures and memory designs described above with reference to FIGS. 1-17. As with other solid-state memory disk replacement schemes, this embodiment eliminates the need for both the disk and its controller card. In addition to reducing size, weight, and power consumption, SpinRAM hard card 1970 drastically reduces access time and eliminates mechanical failures. And, unlike a FLASH-based hard card solution, the memory array of SpinRAM hard card 1970 may be configured to be byte-alterable, has virtually unlimited read/write cycles, and sub-microsecond read and write times.

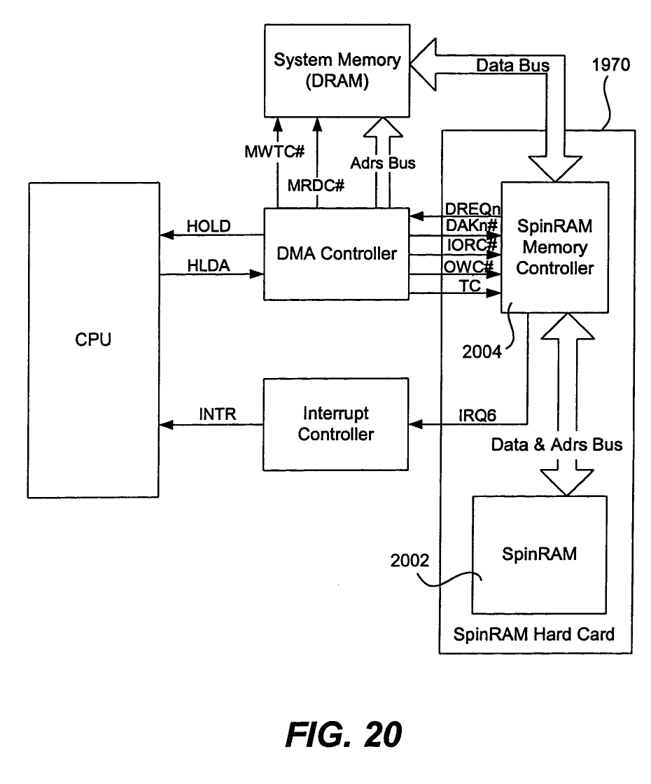

A block diagram of a specific implementation of a SpinRAM hard card 1970 is shown in FIG. 20. SpinRAM memory array 2002 (e.g., memory 100 of FIG. 1) is controlled by SpinRAM memory controller 2004 which, according to a specific embodiment, is located on the same hard card. In PC-bus embodiments such as the ISA embodiment of FIG. 19(b), the bus interface of controller 2004 mimics that of a standard hard disk controller. By contrast, the memory array interface of controller 2004 does not resemble the corresponding interfaces of currently available hard disk controllers. That is, for example, unlike FLASH memories and as described above, SpinRAM technology is current controlled and random access. Controller 2004 is therefore configured to facilitate access to the memory cells to SpinRAM memory array 2002 according to the techniques described above.

The desired functionality of SpinRAM controller 2004 may be implemented, for example, by modifying an existing chip set, using discrete components, or designing a custom controller ASIC. The final interface between controller 2004 and the actual memory cells of SpinRAM array 2002 comprise module interface circuits (not shown) such as, for example, selection matrices 104 and 106 of FIG. 1. According to various embodiments and as described above with reference to the all-metal memory technology, such module interface circuits may be fabricated on the same wafer as the memory cells themselves using the same processes. According to other embodiments, such module interface circuits may be implemented in separate integrated circuits, in which case, SpinRAM memory array 2004 could be packaged as a multi-chip module.

Referring back to FIG. 19(b), SpinRAM cache memory 1956 and SpinRAM system memory 1960 replace the cache and system memories of system 1900. As with SpinRAM hard card 1970, memories 1956 and 1960 may comprise any of the architectures and memory designs described above with reference to FIGS. 1-17.

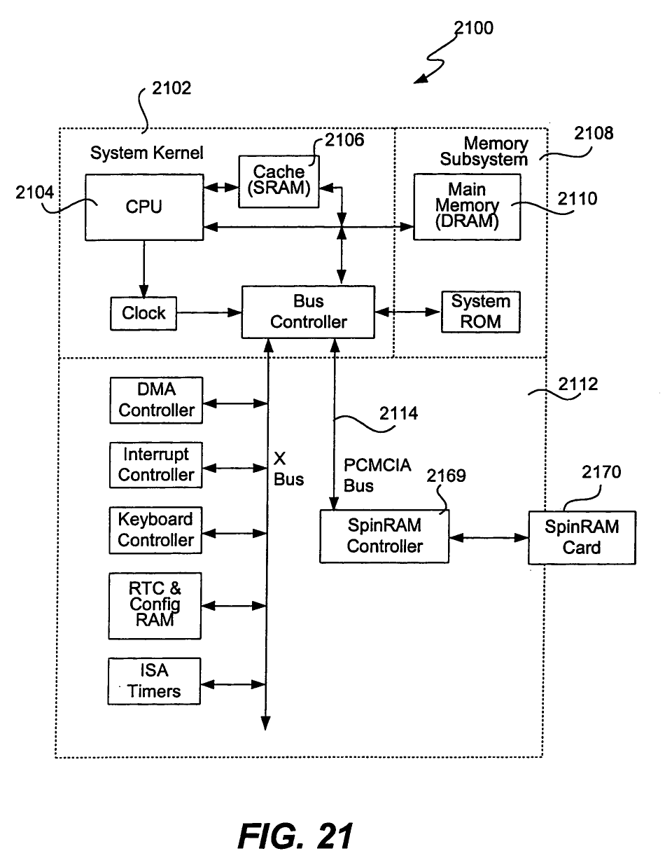

FIG. 21 is a functional block diagram of a personal computer system 2100 having a PCMCIA architecture in which a conventional hard disk drive and its controller (typically coupled to PCMCIA bus 2114 have been replaced by SpinRAM controller 2169 and SpinRAM card 2170. System kernel 2102 includes CPU 2104 and cache memory 2106 which may be the CPU's primary cache or, where the CPU includes an integrated primary cache, the CPU's secondary cache. Memory subsystem 2108 includes the main system memory 2110. PCMCIA subsystem 2112 includes PCMCIA bus 2114 which is coupled to SpinRAM controller 2169.

It should be noted that the examples of specific memory architectures described above are tailored to replace an existing installed base of computer systems in which the ways in which the different types of memories are connected to the system are artifacts of the characteristics of the memory technologies themselves, and may not take full advantage of the performance capabilities of the SpinRAM technology described herein. That is, for example, although plugging a SpinRAM hard card as a replacement for a hard disk drive may represent a simple and fast integration of giant magnetoresistive memory technology into the vast installed base of IBM compatible PCs, a more fundamental memory architecture shift is contemplated which will more readily exploit the advantages of all-metal memories.

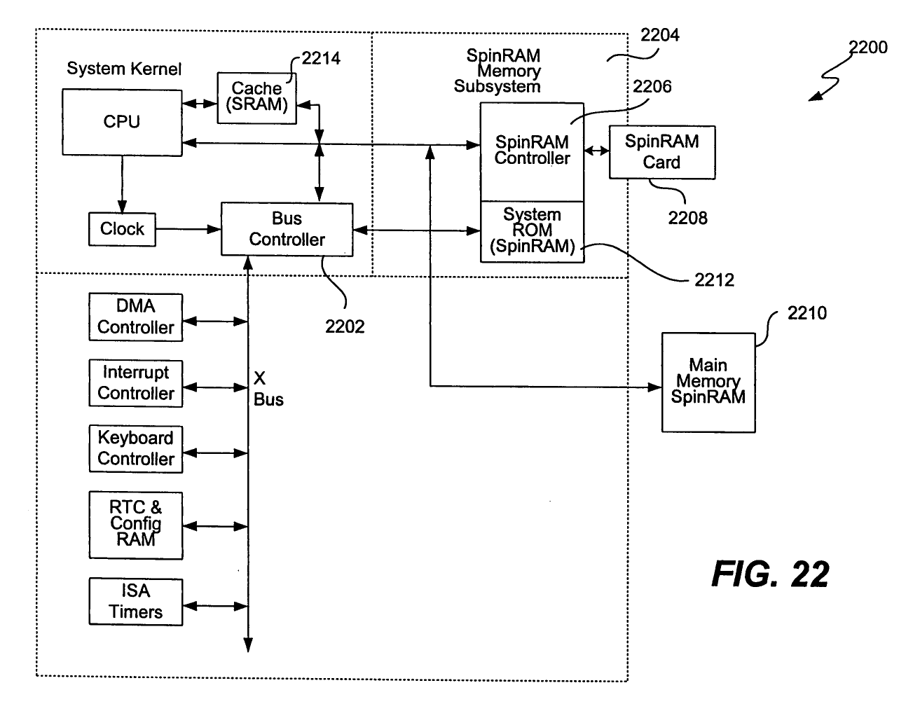

This may be understood with reference to the architectural constraints of the PC bus system. Because the time required for a CPU to retrieve data from a conventional hard disk is primarily a function of disk access time rather than propagation delay through the bus controller, there is little or no penalty associated with connecting the hard disk to the CPU through the controller. Of course, this is not the case for cache and system memory which are directly connected (architecturally) to the CPU. With the fast access times of SpinRAM technology, it is desirable to connect SpinRAM-based mass storage to the CPU in such a way to avoid the penalty imposed by conventional PC bus architectures. Such an embodiment is shown in FIG. 22.

FIG. 22 is a block diagram of computer system 2200 using SpinRAM technology for system memory, system ROM, and mass storage. According to this embodiment, the architecture of computer system 2200 is designed with the capabilities of giant magnetoresistive memory technology in mind, e.g., access to mass storage via bus controller 2202 and a PC bus is eliminated. A SpinRAM memory subsystem 2204 comprises SpinRAM controller 2206 to which SpinRAM card 2208 connects. SpinRAM card 2208 may, for example, be implemented as discussed above with reference to SpinRAM card 1970. Main memory 2210 is also part of memory subsystem 2204 and comprises a SpinRAM array.

System ROM 2212 is also implemented as a giant magnetoresistive SpinRAM array. System ROM 2212 may be used, for example, to store a PC's BIOS code or user applications for a palm top device. Using the byte alterable SpinRAM for system ROM allows the capability of updating what is typically hard coded information in many of today's computer systems. According to another embodiment, cache memory 2214 may also be implemented using SpinRAM technology.

It will be understood that SpinRAM memory subsystem 2204 may be configured in a variety of ways. That is, subsystem 2204 may comprise different subsets of memories 2208, 2210, 2212 and 2214. In addition, different subsets of these memories may be integrated in the same device or configured as separate modules.

It will be understood by those skilled in the art that changes in the form and details of the memory technologies described above may be made without departing from the spirit or scope of the invention. For example, specific embodiments have been described herein with reference to a selection matrix implemented using single input transpinnors (e.g., see FIG. 17). It will be understood, however, that a two input transpinnor such as transpinnor 1302 of FIG. 13 may also be used to implement such a selection matrix. That is, two line selection striplines could supply magnetic fields to the two-input transpinnors in the matrix array with a separate power current input.

In addition, it will be understood that the number of memory access lines required to access information in the individual memory cells in a memory array will vary in accordance with the structure of the memory cells and the number of bits stored in each. The number and types of access lines for a given memory cell structure may be determined by one of skill in the art of memory technology from, for example, the descriptions of various GMR memory cells herein.

Furthermore, although an example of a unified memory architecture has been described herein in the context of specific architecture types, it will be understood that a wide variety of memory architectures for computers and other systems are enabled.

As discussed above, in one such architecture a rotating disk is physically but not logically replaced with a SpinRAM array. That is, a memory controller is configured such that the rest of the system operates as if it is connected to a rotating disk, but the controller interacts with the SpinRAM array. Such an architecture eliminates the disadvantages of rotating disk memories (e.g., long access times, susceptibility to environmental conditions) without the need for extensive retrofitting or redesign of installed computer base.

Another contemplated architecture involves the partial replacement of system memory with SpinRAM technology. The SpinRAM portion of the system memory could, for example, be used to store data that must be preserved in the event of a power failure. According to a specific embodiment, the SpinRAM portion of the system memory store a small RAM file system which provides very fast access to a subset of the system's overall file stores.

Of course full replacement of system memory with SpinRAM technology is contemplated as well. This would allow expansion of the use of system memory to include data which must be maintained through power loss and system reboots. Such a system could recover much faster than conventional systems after a power down has occurred. All that would need to be done is the normal processor power-up diagnostics and the restoration of the internal machine state. No time would be wasted reloading information from mass storage to system memory.

Another contemplated architecture replaces both system DRAM and magnetic disk storage with SpinRAM technology. The replacement of both of these memories makes possible the unified memory architecture in which most or all of a computer system's memory is implemented using a single technology, i.e., SpinRAM. Further variations of such an architecture include the replacement of other memories with SpinRAM technology including, for example, cache memory and system ROM.

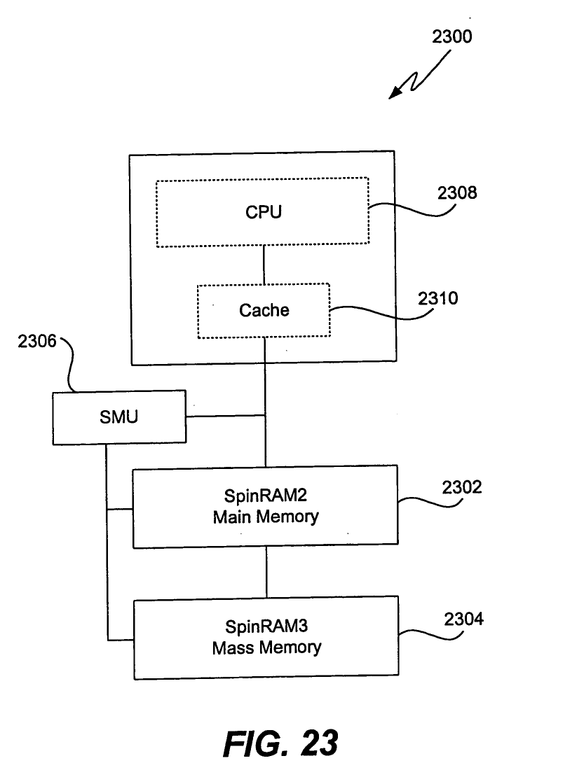

A simplified block diagram of a generalized computer system based on SpinRAM technology is shown in FIG. 23. The design of system 2300 is based on a two-tier architecture incorporating at least SpinRAM2 (2302) and SpinRAM3 (2304), i.e., SpinRAM replacements for DRAM and rotating disk, respectively. The main memory pool is based on SpinRAM2 (RAM speed memory), and secondary file storage on SpinRAM3 (disk density). A SpinRAM Management Unit (SMU) 2306 handles transfers between memories 2302 and 2304 and CPU 2308, providing much the same functionality as a conventional cache management unit in a computer system employing the cache memory paradigm. A cache memory 2310 may be provided close to CPU 2308 and may comprise SpinRAM1 technology. An level one cache memory (not shown) may be provided integrated with CPU 2308.

It should be noted that SpinRAM technology allows the cache paradigm to be carried throughout system 2300 regardless of the number of SpinRAM levels. Thus, for example, CPU 2308 receives data from its level one cache. The level one cache receives data from the level two cache (e.g., cache 2310). The level two cache receives data from main memory 2302. Main memory 2302 acts as a level three cache in concert with SMU 2306. Finally, main memory 2302 receives data from mass storage memory 2304 which acts as a fourth level cache.

The foregoing describes the basic theory of operation underlying SpinRAM technology and transpinnor-based electronics and a few representative examples of the wide variety of applications for which such technology is suited. As should be appreciated at this point, SpinRAM and other transpinnor-based electronics may be employed as the basic building blocks for virtually any type of electronic circuit or system currently implemented using conventional semiconductor technologies. However, given the ubiquitous nature of such conventional technologies, it is desirable to provide interface circuitry which is capable of translating signal between the transpinnor and semiconductor domains. Suitable interface technology is described in U.S. Patent Publication No. US-2004-0075152-A1 published on Apr. 22, 2004 (Attorney Docket No. IMECP016), the entire disclosure of which is incorporated herein by reference. As will become apparent, various embodiments of the invention may employ such interface technology (and any suitable alternatives) to integrate all-metal SpinRAM with conventional semiconductor circuits and devices.

As described above, SpinRAM may be used to implement a wide variety of memory systems and subsystems in virtually any computing configuration. More generally, SpinRAM may also be employed in any type of device the operation of which may be characterized by a state or sequential machine to render such devices nonvolatile. More specifically, embodiments of the invention enable the various components of a system to be kept operations ready when brought up from standby or unpowered modes through the use of an all-metal nonvolatile memory which has true random bit access and virtually unlimited write cycles.

According to various embodiments of the invention, a nonvolatile metal RAM, e.g., SpinRAM, is employed to preserve the last state of a sequential machine, thereby rendering the device based on the state machine nonvolatile. “Metal RAM,” and more generally “metal electronics,” is circuitry based on giant magnetoresistance (GMR) and involves no semiconductors. The foundation for such metal electronics is the transpinnor, an active element made of GMR films as described above. In the case of the magnetic SpinRAM, the support circuitry as well as memory array are made of GMR films. Thus, an entire block of SpinRAM (including support electronics) may be made of metal layers and insulators alone, with no semiconductors.

Systems and devices embodying sequential machines (i.e., algorithmic state machines, which form the basis for controllers, microcontrollers and other computers) have their power removed for the time they are out of operation. In order to resume the active mode, the device needs access to the information on its last state prior to having had its power removed.

The time needed to initialize the work memory and initialize all system registers in the typical computing system greatly depend on the computing configuration. Memory initialization time results from the transfer of the needed OS routines, peripheral drivers, and basic applications from the hard disk to the main memory. Register initialization time results from the sequential transfer of the content of all system registers from a backup system, a memory area that is either nonvolatile or permanently powered.

The current and future needs for system nonvolatility may be considered in the context of three types of processors: 1) embedded control computers, 2) real-time control systems, and 3) general-purpose computers.

In the first category, embedded control computers are becoming ever more pervasive, primarily because they can be implemented as single-chip stand-alone devices that can solve problems previously responsive only to interconnected larger modules. The use of nonvolatile memory can be critical for these systems. Essential state information must be carried forward from one activation to the next. This may not include the entire register and memory content, but is often a significant part of it. Additionally, these control computers are typically generalized, with a set of parameters to be tailored to the specific implementation and system, either when the unit is manufactured, first installed, or configured externally. These parameter values must be maintained even when power is removed. For these systems the volatility problem is completely solved by a nonvolatile register set.

In the past, many of these small computers have been used in isolated systems, where they are totally self-reliant and therefore must provide reliability to the full extent required by the system into which they are embedded. This usage will continue, but a new dimension has been added. Interconnectivity of these small computers is being motivated by the availability of high-speed serial-wired connection technology as well as by optical and wireless technologies. Because single-chip computers can perform both their original functions and these added communication tasks, they need to maintain not only their internal state, but also the state of the communication system and that of close neighbors to avoid continuous reconfiguration. This further increases their need for nonvolatility.

Currently, nonvolatility is provided in these embedded computers by a combination of flash and battery-backed SRAM. Both are problematic. Flash has long write times and a limited number of write cycles. Moreover, like all semiconductor memories, flash is becoming increasingly more vulnerable to radiation as cell size decreases. Roughly half of all soft errors are now accounted for by radioactive impurities in packaging materials. Both of these limitations impose severe constraints on how flash is used in embedded applications. Backup batteries have limited capacities, less than ideal temperature ranges, and may have mechanical mounting issues. Many embedded systems must function in very harsh environments.

In the second category are computers that serve in real-time control systems. These computers—which may be very large, very small, or anywhere in between—function as part of larger systems, in which the real processing involves interaction of machines and equipment that form part of the system. Human interaction is typically limited to operator interfaces. In these systems there is usually enough redundancy so that the processing load can be shifted to other computers if one goes down. Therefore, state restoration can proceed more leisurely than for embedded systems. However, for critical components—and depending on the design of the system—the need for nonvolatility is just as great as for the first category. Typically, these systems have an OS, and state recovery can be functionally built into it.

In the third category are general-purpose computers, e.g., handhelds, laptops, desktops and servers. Their technology is basically human-interface and processing oriented. In these systems, nonvolatile memory, though not as critical as in either of the first two types, is certainly desirable. For example, at the current state of technology, e.g. Windows XP, a 3 GHz computer can take as much as several minutes to power up. These times grow significantly, depending on the configuration to become operational, e.g. when part of a networked cluster. A suitable nonvolatile technology can be a major contributor to improving user and system productivity.

The current state-of-the-art for power-management logic in computing systems, either on chip or as a separate component, is to detect the transition into the power-down mode by generating a power-down signal. The power-supply module is typically equipped with a power capacitor that creates a power reserve for a certain number of system cycles. This ensures that once the power-down condition has been detected and a power-down signal generated, the system will still be able to perform additional cycles, e.g. on the order of 10, until it grinds to a complete halt. For a 1 GHz system clock this translates into 10 ns, not nearly enough to back up the system registers into the nonvolatile portion of the main system memory, even if such nonvolatile memory exists. A capacitor-type power-down reserve that provides enough reserve for the computer to save all registers into the nonvolatile portion of the main memory is not economically feasible in stationary computers (like desktop PCs, work stations, servers), and even less so in portable (notebooks, laptop PCs) or mobile computers (palmtop PCs), which have severe space constraints.

Therefore, according to various specific embodiments of the invention, a metal-electronics system is provided that renders existing semiconductor computing components nonvolatile. According to a specific embodiment, two subsystems are provided on a single chip; a second set of registers (e.g., SpinRAM registers) to duplicate the contents of the semiconductor register set; and an interface between the semiconductor set and the metal set of registers, containing both semiconductor and metal logic.

The properties of SpinRAM that can keep computer components operations ready when brought into the active mode are that—unlike flash—it has true random-bit access, is fast (SRAM speed or faster), has virtually unlimited write cycles, and is inherently radiation resistant. SpinRAM and transpinnor electronics will thus enable a nonvolatile computer component, even with the time constraints imposed on the system by an economic power-down reserve system. In addition, such use of SpinRAM will allow the computer component to almost immediately resume operation from the point of interruption when returning into the active mode from the standby or unpowered modes.

According to different embodiments of the invention, metal memory cells (e.g., SpinRAM cells) can be used to preserve the last state of the system, and thereby render a sequential machine nonvolatile, in at least two different ways. According to a first set of embodiments, a second set of metal registers is built into existing semiconductor computing components to duplicate the functionality of the semiconductor register set for each system module separately. These registers will be referred to herein as “shadow” registers. According to a second set of embodiments, the entire semiconductor register set is replaced by a SpinRAM array of registers. System-module examples that can be made nonvolatile according to either set of embodiments include central processing units, graphic processing units, arithmetic processing units, input/output units, storage units and many more. In both cases the metal registers realize the desired goal, i.e., register contents are preserved upon loss of power.

Shadow registers are advantageous for some applications because they leave the conventional system module architecture largely unchanged. Replacement of the semiconductor registers by SpinRAM requires more complex system changes, but the register set in such embodiments will not lose its content when power is removed, and there will therefore no longer be need for either the register backup cycle prior to power removal or register initialization cycle after power is restored. That is, initialization time will be zero.

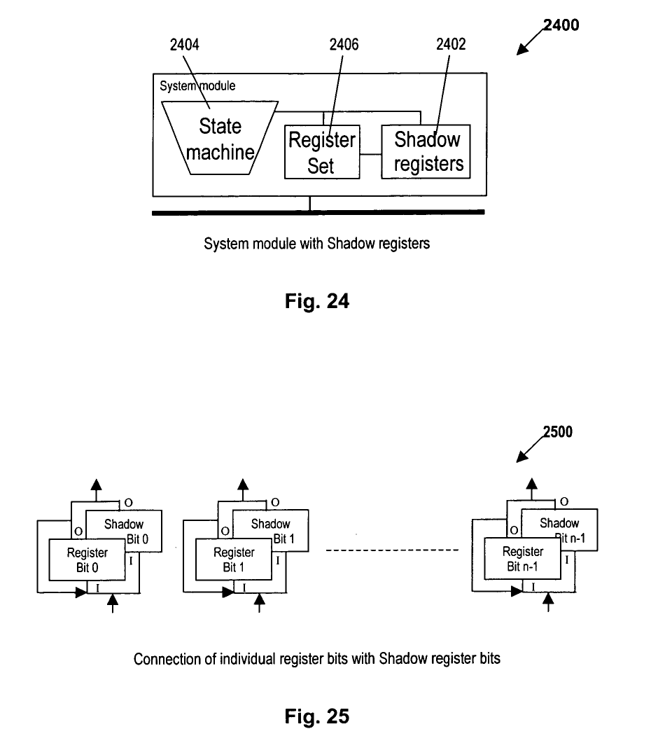

FIG. 24 shows the block diagram of a system module 2400 with a self-contained shadow register block 2402. This block includes a metal register set (e.g., employing the GMR based memory cells described above) and metal/semiconductor interface circuitry. The operation of system module 2400 is controlled by a semiconductor controller or processor represented by state machine 2404. According to some embodiments, the design of shadow register set 2402 reflects the architecture of the semiconductor registers 2406 to be shadowed which, in turn, is based on the existing microcontroller or digital-subsystem design. To distinguish the two register sets, we hereafter refer to the two different sets as semiconductor registers and shadow registers.

Transpinnor and GMR logic levels are easily adapted to one another and to CMOS levels thereby enabling seamless connection of logic in and among CMOS and GMR circuits. Circuits suitable for implementing interfaces between current-based transpinnor logic levels and voltage-based semiconductor logic levels are described in U.S. Patent Publication No. US-2004-0075152-A1 incorporated herein by reference above. Using such techniques, all types of GMR film blocks can be monolithically embedded into CMOS structures. Shadow registers are an example of the unique capabilities—nonvolatility in this case—that GMR film blocks can confer to mature CMOS system modules such as microcontrollers and microprocessors.

According to various embodiments, shadow registers can be activated in a variety of ways. For example, in an automatic mode, the system module writes into the shadow register set every time a semiconductor register is updated. Alternatively, the contents of all shadow registers may be saved upon receiving a signal from the system, e.g., a power-down signal generated by the power management logic. Still other alternatives might involve updating shadow register contents periodically or in response to specific events.

According to a specific embodiment, the input and output of a semiconductor register bit and the corresponding shadow register bit are connected. The output of the configuration is fed back to its input. FIG. 25 illustrates such a configuration for an n-bit register 2500. The backing up of semiconductor register content occurs in the automatic write mode by having information clocked into the shadow register bit every time it is clocked into the corresponding semiconductor register bit. Alternatively, this operation occurs only when triggered by a signal, e.g. the power-down signal generated by the power-management logic of the system. Restoration of register content involves the transfer of the contents of each shadow register into the corresponding semiconductor register. This may be triggered, for example, by a signal, e.g. the initialization signal issued by the power-management logic of the system, every time power is applied to the component.

Embodiments in which the shadow registers are frequently updated are suitable when the write speed of the shadow register bits is equal to or faster than that of the semiconductor register bit. Such embodiments may even be suitable when the write speed of the shadow register bits is somewhat slower than that of the semiconductor register bit, provided the slowdown in speed is acceptable. On the other hand, embodiments employing less frequent updates may be called for when the write speed of the shadow register bits is significantly slower that that of the semiconductor register bits. This avoids the system slow down which would otherwise result writing to the slower shadow registers on every write cycle.

According to some embodiments, shadow register bits are in close physical proximity to their corresponding semiconductor register bits. The two bits of a pair may also be logically close, i.e., they may be connected point-to-point with no other logic layer between them. Therefore, any information transfer between the semiconductor register bit and the shadow register bit can take place in a single system clock cycle, e.g. on the order of 1 ns for a 1 GHz system clock. In such embodiments, this is also the time required to transfer information between the two register sets regardless of the number of register bits in the system because the transfers are made in parallel. This is ample time to back up all semiconductor registers into their respective shadow registers in the time typically made available (˜10 ns) by an economic power-down reserve system. Because the shadow register set allows cutting off power with only two clock cycles notice (i.e., one clock cycle to enable register output, and one cycle to latch the contents into the shadow registers), and restores the content of all system registers simultaneously in a single clock cycle, the system can reduce power consumption by cutting power more frequently.

A further advantage associated with the use of shadow register bits as described herein is that both the content backup and content restoration routines may be implemented in the component hardware, therefore eliminating the need for complex software routines to perform these tasks. That is, such routines consume significant system resources themselves in terms of software, power and time. Additionally, the occurrence of any system problems during the operation of such routines represents a potential disaster.

As a reference for register initialization times, some subsystems use flash as backup for configuration states; this is the case for FPGA chips. In this situation, recovery requires reading sequentially from flash and setting the SRAM-configuration control registers through a serial shift register. This typically takes on the order of milliseconds rather than the 1 ns or less for the specific embodiments of the invention described herein.

Thus, some embodiments of the present invention provide all-metal registers that are built into semiconductor components which mirror the registers of these components. These registers have the capability to store the module register data and eliminate the need to store these data in the system memory. According to more specific alternative and/or complementary embodiments, (1) the all-metal memory block is automatically updated in a transparent mode every time the corresponding semiconductor register is updated; (2) the all-metal memory block is automatically updated in a transparent mode, as triggered by either a self-initiated or a system-initiated signal; (3) the all-metal memory block is automatically updated whenever power is cut off from the respective module, as triggered by a self-generated or by a system-generated signal; and (4) the module registers are initiated by transferring the contents of the all-metal memory block to the register set every time the system module is powered.

The conversion from GMR logic levels to CMOS or TTL levels requires a conversion translation from the GMR output. The GMR output may be characterized by a small open-circuit output voltage or a moderate short-circuit output current. The preferred output is the short-circuit load where the logic levels are currents. Short-circuit output has the advantage that output-load capacitance effects, which normally cause slower responses, are significantly reduced. Open-circuit output operation is also possible, but with load-capacitance effects present.

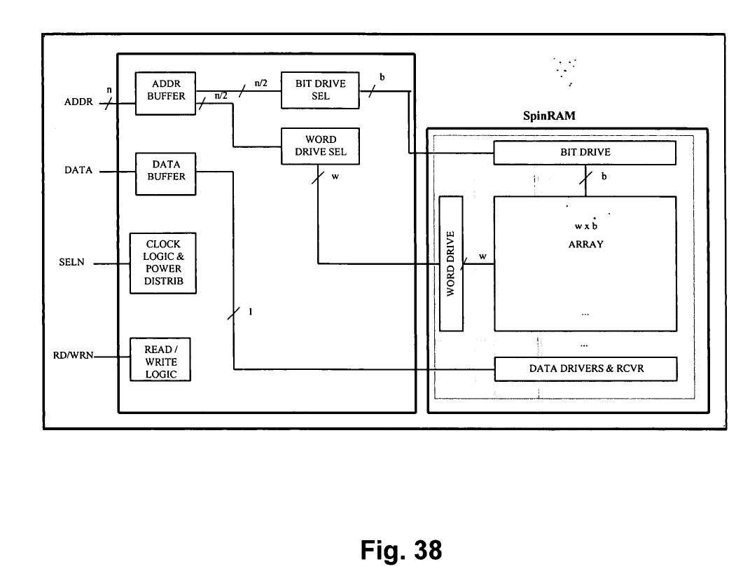

A variety of exemplary interface circuits will now be described which may be employed to effect conversion between all-metal GMR circuitry and conventional semiconductor circuitry. It will be understood with reference to this description and the accompanying drawings that these or similar interface circuits may be employed, for example, to implement the tight coupling between semiconductor register bits and all-metal GMR register bits referred to above. It will also be understood that these or similar interface circuits may be employed (as will be described with reference to FIGS. 37 and 38) to facilitate replacement of a semiconductor register set in a semiconductor-based system or component with an all-metal register set configured as an array of Spin RAM. In such embodiments, the interface circuitry would provide the signal translations between the semiconductor system or component and the embedded SpinRAM array.

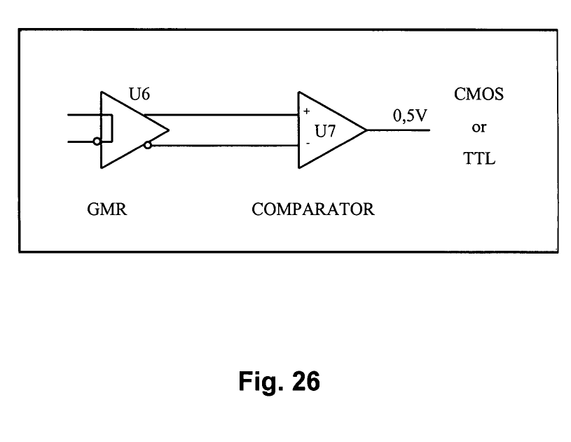

FIG. 26 shows the case where a GMR element U6 is operated with essentially open-circuit output. The GMR element U6 drives a high-impedance comparator U7 that converts the GMR output voltages to CMOS or TTL logic levels. An example comparator that may be employed for such an interface is the LM310. The advantage of this circuit is its simplicity. It can be used in applications where speed is not an issue and the GMR configuration has sufficient overdrive capability. One disadvantage is the capacitive loading effects (in cases where that is important). In GMR-element designs where the open-circuit output voltages are especially small, they might approach the differential offset voltage of the comparator. This may also cause significant speed reduction because of insufficient overdrive. In situations where these issues do not arise, the circuit should work satisfactorily with off-the-shelf parts.

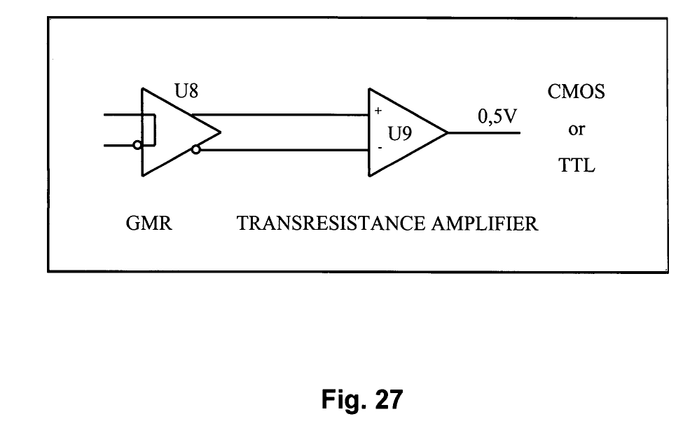

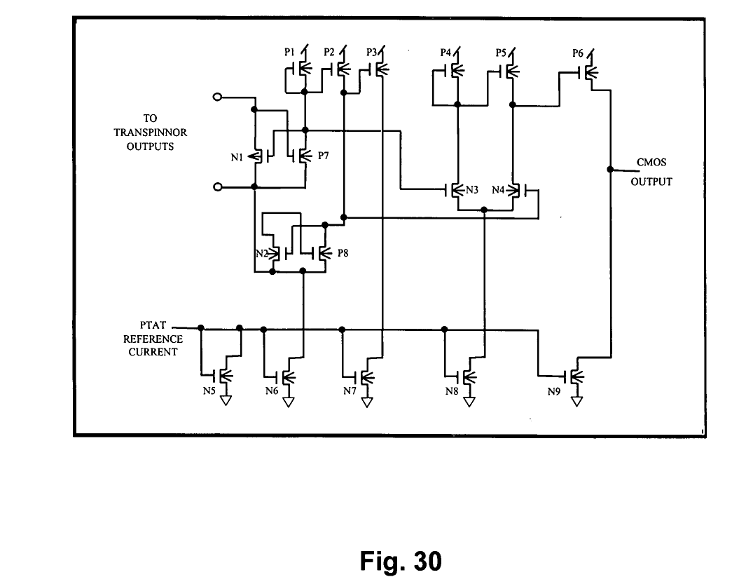

FIG. 27 shows the case where the output of GMR element U8 is operated in essentially short-circuit mode, and drives a transresistance amplifier U9. The characteristics of the transresistance amplifier U9 are short-circuit input and a gain characteristic described as output voltage per unit input current. Thus, transresistance amplifiers often have their gain expressed in ohms. An exemplary transresistance amplifier suitable for such an implementation is the LM359. In this case, transconductance amplifier U9 converts the GMR logic currents to CMOS or TTL voltages. An exemplary CMOS transresistance design is illustrated below in FIG. 30.

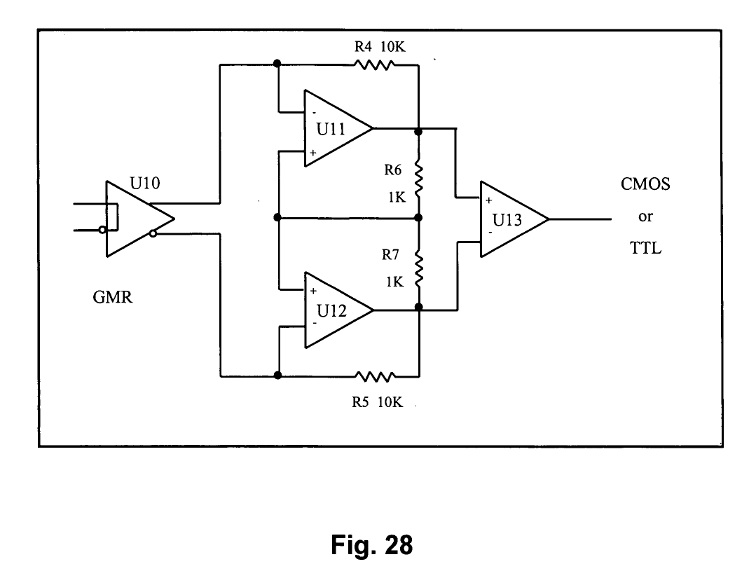

FIG. 28 is similar to FIG. 27 and shows a transresistance amplifier comprising op amps (U11, U12 and U13) connected to a GMR gate U10. In this case U11 and U12 are each connected in charge amp configurations with R4 and R5, so that they have very low input impedances. The charge amps reference terminals are centered with R6 and R7. The outputs of U11 and U12 can then be converted to CMOS or TTL outputs with a comparator U13. The circuit structure is similar to an “instrumentation amplifier.” This circuit provides the GMR gate with a self-centering short-circuit load while using a high-speed comparator to obtain the CMOS or TTL logic voltages. It will be understood that other circuit structures are possible to achieve the same effect.

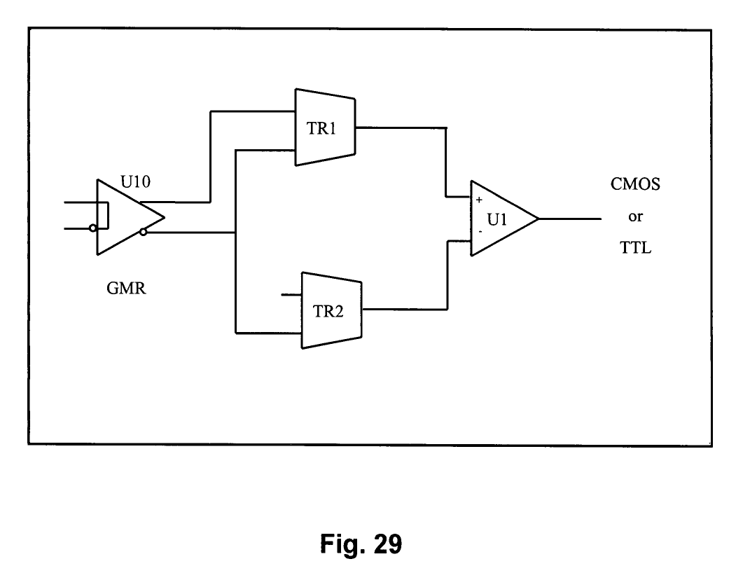

FIG. 29 shows a block diagram of an exemplary CMOS implementation of a transresistance interface to the transpinnor outputs. This example is based on the transresistor model described in A Simple 2-Transistor Transresistor by Schlarmann and Geiger, IEEE Electronics Letters, pp. 1386-87, December 2001, the entire disclosure of which is incorporated herein by reference for all purposes. The transresistor TR1 provides the short-circuit load required by the transpinnor. It uses one of the transpinnor pins as a reference point and has a built-in offset. TR2 is connected to the reference side of the transresistor, but its other input is open (zero current) so that it provides the zero output for use by the comparator U1.

FIG. 30 shows an exemplary CMOS implementation of the circuit of FIG. 29. Transistors P1, P7, and N1 implement TR1. Transistors P2, P8, and N2 implement TR2. The comparator U1 is implemented with P4, P5, P6, N3, N4, N8, and N9.

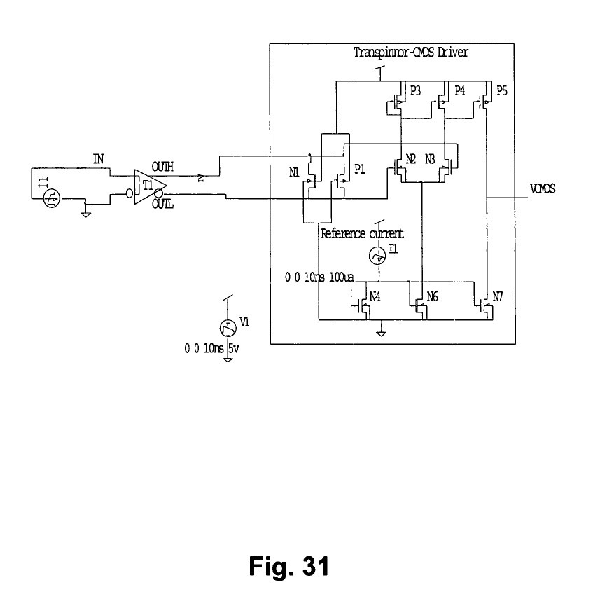

FIG. 31 illustrates yet another possible configuration similar to that in FIG. 30. In this case, the shorted load is implemented as a transmission gate, N1 and P1. The small voltage across the transmission gate is converted to CMOS levels by the standard CMOS comparator (N2 thru N7 and P3 thru P5).

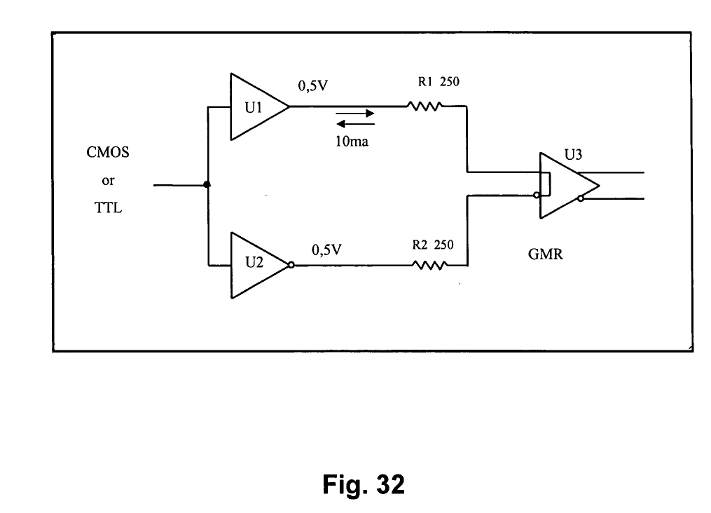

The conversion of CMOS or TTL logic signals to signals suitable for GMR logic is a simple operation in which the CMOS or TTL output voltages are converted to currents. FIG. 32 shows an exemplary arrangement that might be used when the GMR logic levels are +10 mA and −10 mA. In this case, the CMOS or TTL signal is used to drive a differential output using a buffer and inverter structure, U1 and U2. The CMOS or TTL voltages are converted to currents by resistors R1 and R2 and used as the input to the GMR gate U3. The input of U3 is a very low resistance and can be assumed to be zero ohms for calculations.

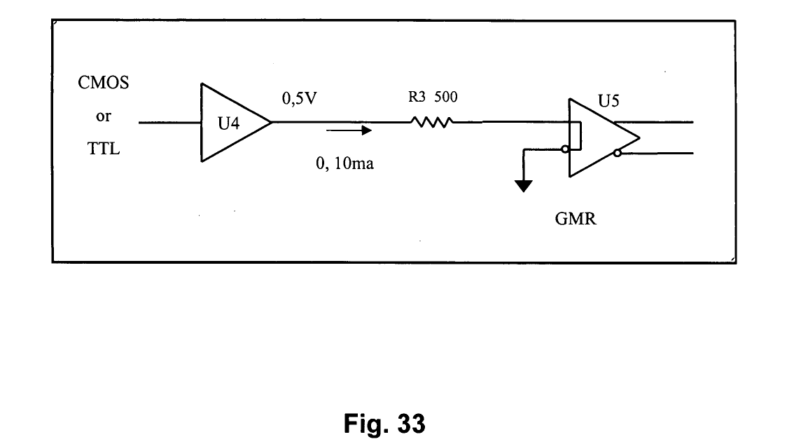

FIG. 33 shows another example, where the GMR logic levels are 0 and +10 ma. In this case a single CMOS or TTL gate U4 is used as a buffer. The resistor R3 is used to convert the CMOS or TTL output voltage to current as needed by the GMR gate U5. In this case, the GMR gate U5 can be returned to ground instead of being driven differentially.

A CMOS design can also make use of the excellent current-source capability of CMOS to fashion an output driver that provides the logic-level currents directly in a regulated fashion. The normal practice is to refer current sources to a bandgap-style regulator, which has a reference current output commonly called a PTAT.

“PTAT” is an abbreviation for Proportional To Absolute Temperature. PTAT is a commonly used term in CMOS design. In CMOS analog circuit design, the current practice is to design a power supply regulator commonly referred to as a bandgap regulator. A typical bandgap regulator includes a pair of diodes used to produce a reference current that is PTAT and used to compensate temperature variations to produce the bandgap voltage for the regulator. It is common practice to also use this PTAT current (since it is there already) as a reference to bias the rest of the chip through the extensive use of CMOS mirror circuits. Virtually everywhere a bias current is needed, a PTAT mirror is used—examples include amplifiers, comparators, digital-to-analog reference currents, external device biases, etc.

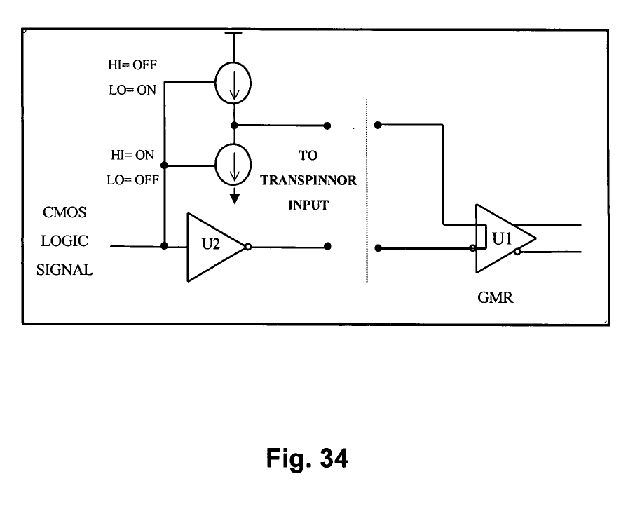

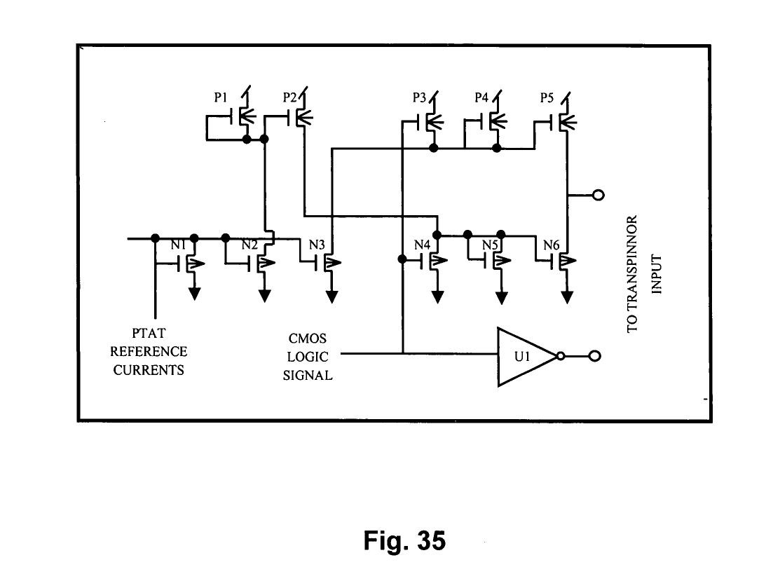

FIG. 34 shows a block diagram of a CMOS drive circuit for the transpinnor input of GMR element U1. FIG. 35 shows a more specific implementation of a design for such a circuit that assumes the presence of a PTAT to form the output currents. Once into the current regulating region, the currents hold very constant regardless of power supply voltage. FIG. 34 shows the transpinnor reference side (connected to inverter U2) being high if the lower current source is ON and low if the upper current source is ON.

In FIG. 35, transistor N1 is the main PTAT mirror from which the other current sources are derived. N2, P1 and P2 provide a current reference to N4, N5, and N6. N4 is a switch that turns N5, N6 ON and OFF. N5 is the mirror for N6. N6 is the output current source. N3 provides a reference current to P3, P4, and P5. P3 is a switch that turns P4, P5 ON and OFF. P4 is the mirror for P5. P5 is the upper output current source. Since the switches are interconnected as shown, the CMOS logic signal will turn one ON while the other is OFF, so that only one output current source is ON at a time. Since both current outputs are referred to the PTAT, the output-logic current levels will hold proper values as long as the power supply is greater than the sum of p- and n-thresholds, typically about 1.5 volts or greater.

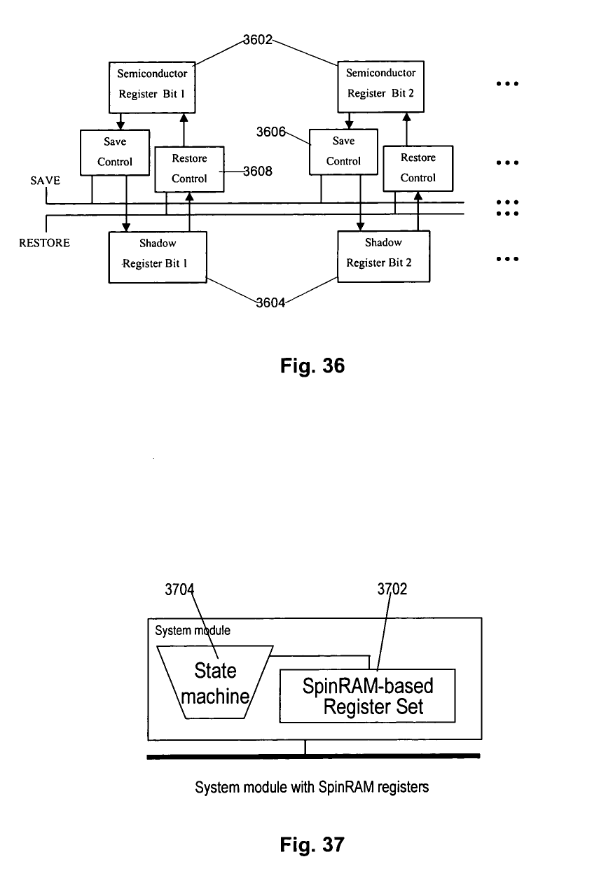

FIG. 36 shows a more detailed representation of the manner in which semiconductor register bits and the corresponding shadow register bits may be connected according to a specific embodiment of the invention. When GMR memory elements are used to implement a tightly coupled shadow register as described above, each semiconductor register bit 3602 has a corresponding shadow memory bit 3604. According to a specific embodiment, a simple latching control mechanism is provided to both save the semiconductor register and to restore it.

The SAVE signal is generated by external circuitry and causes the semiconductor register bits to be copied into the shadow memory bits. According to one implementation, the SAVE signal is only issued at times when the semiconductor contents are in a state that may need to be recovered. The RESTORE signal is also generated by external circuitry and causes the shadow memory contents to be restored into the semiconductor register. The RESTORE signal is issued only when a recovery of the saved state needs to be performed.

Save Control circuit 3606 is a control circuit that causes the contents of the semiconductor register bits to be recorded into the shadow memory bits. The circuitry can be a simple AND gate with appropriate level shifting to convert the voltage implemented logic levels in the semiconductor register into the currents needed to set the state of the GMR memory elements.

Restore Control circuit 3608 is a semiconductor control circuit that converts the current output of the GMR memory elements into voltage levels and then AND's these with the RESTORE signal to set the semiconductor register bits.

As will be understood, the specific implementations of the save and restore controls are dependent on the design of the semiconductor register and on the design of the shadow register. The discussions provided above relating to transpinnor-based circuits and the interfacing of semiconductors and all-metal GMR based circuitry, and the information provided in the patent documents incorporated herein by reference above, are sufficient to enable one or ordinary skill in the art to implement the appropriate design.

According to another generalized set of embodiments, the present invention provides an all-metal nonvolatile register set, built into a semiconductor-based system component to replace the semiconductor-based register set. Such a configuration is shown in FIG. 37. The interface between the SpinRAM register set 3702 and the semiconductor-based state machine 3704 (e.g., which may represent any type of controller or processor) may be implemented as described in U.S. Patent Publication No. US-2004-0075152-A1 incorporated herein by reference above.

A block diagram of exemplary interface circuitry between the CMOS circuitry of a semiconductor-based component and a SpinRAM array is shown in FIG. 38. The various blocks may be implemented using the circuits described above. It will be understood that the CMOS circuitry and the SpinRAM may be implemented in separate chips or may be manufactured on the same substrate as a single-chip. It should also be understood that the basic configuration shown may be generalized to any array or data path size.

The input interface to the semiconductor circuitry shown on the left-hand side corresponds to a CMOS set of controls. The one-bit data line DATA is tri-stated and receives the input value for a write and sends the output value during a read. The chip select SELN (active low) enables read or write operations. A high signal for the read and write control RD/WRN indicates a read, and a low a write. The memory-operation cycle starts when SELN is pulled low or the RD/WRN signal changes. During changes, the signals on the ADDR lines must be stable.

The blocks in the interface perform the following functions. The ADDR BUFFER block is a buffer register with gating logic to capture the address when a read or write operation starts. The register holds the address stable during the operation. The BIT DRIVE SEL block is an address decoder and an analog current generator that produces the half-select bit (column) drive currents for the SpinRAM column-driver transpinnors. Only one of these drivers is active at a time. The currents generated are dual polarity and two levels corresponding to the read currents for switching the SpinRAM soft layer and corresponding to the write currents for switching the SpinRAM hard layer.

The WORD DRIVE SEL block is an address decoder and an analog current generator that produces the half-select word (row) drive currents for the SpinRAM row-driver transpinnors. It operates similarly to the BIT DRIVE SEL circuitry. The DATA BUFFER block is a 1-bit buffer register with logic to control write-operation currents and to receive the bit read during a read operation. During a read, the tri-stated input line is activated to output the bit read.

The READ/WRITE LOGIC block receives the read or write request along with the SELN signal to start a read or write operation sequence. A state machine sequences through a set of states to drive the SpinRAM memory selectors. For reads, a sequence of operations are performed to determine whether the selected bit is a 1 state or a 0 state. The proper timing sequences for applying the select currents and gating the output onto the DATA line are also generated in this block. The CLOCK LOGIC & POWER DISTRIB block receives control from the SELN signal going low and initiates a sequence of actions conditioned by the RD/WRN pin state.

In addition to these embodiments and as described above, SpinRAM can also be used as nonvolatile main memory for any computing configuration, thus rendering the memory-initialization cycle unnecessary.

While the invention has been particularly shown and described with reference to specific embodiments thereof, it will be understood by those skilled in the art that changes in the form and details of the disclosed embodiments may be made without departing from the spirit or scope of the invention. In addition, although various advantages, aspects, and objects of the present invention have been discussed herein with reference to various embodiments, it will be understood that the scope of the invention should not be limited by reference to such advantages, aspects, and objects. Rather, the scope of the invention should be determined with reference to the appended claims.

1. A device comprising:
a semiconductor controller operable to control operation of the device according to a state machine comprising a plurality of states;
a plurality of semiconductor registers operable to store the states during an active mode of the device; and
a plurality of shadow registers operable to store the states during a reduced power mode of the device, the shadow registers comprising nonvolatile random-access memory operation of which is based on giant magnetoresistance (GMR); and
interface circuitry operable to transmit the states between the semiconductor registers and the shadow registers.

2. The device of claim 1 wherein the semiconductor registers comprise semiconductor memory cells having inputs and outputs, and wherein the shadow register comprise GMR memory cells having inputs and outputs, and wherein the inputs of the semiconductor memory cells are coupled to the inputs of the GMR memory cells via the interface circuitry, and wherein the outputs of the semiconductor memory cells are coupled to the outputs of the GMR memory cells via the interface circuitry.

3. The device of claim 2 wherein the outputs of each pair of semiconductor and GMR memory cells are fed back to the inputs of the pair of semiconductor and GMR memory cells.

4. The device of claim 1 wherein the interface circuitry is operable to transmit the states from the semiconductor registers to the shadow registers in response to an indication of a transition from the active mode to the reduced power mode.

5. The device of claim 1 wherein the interface circuitry is operable to transmit the states from the semiconductor registers to the shadow registers each time the semiconductor registers are updated.

6. The device of claim 1 wherein the interface circuitry is operable to transmit the states from the shadow registers to the semiconductor registers in response to an indication of a transition from the reduced power mode to the active mode.

7. The device of claim 1 wherein the shadow registers comprise memory cells, each of the memory cells comprising:
a plurality of magnetic layers, at least one of the magnetic layers being for magnetically storing one bit of information;
a plurality of the access lines integrated with the plurality of magnetic layers and configured such that the bit of information may be accessed using selected ones of the plurality of access lines and the giant magnetoresistive effect; and
at least one keeper layer;
wherein the magnetic layers, the access lines, and the at least one keeper layer form a substantially closed flux structure.

8. The device of claim 1 wherein the reduced power mode comprises any of a standby mode, a power saving mode, a sleep mode, a power fault mode, and an off mode.

9. The device of claim 1 wherein the interface circuitry operable to transmit the states between the semiconductor registers and the shadow registers entirely under hardware control.

10. The device of claim 1 wherein the interface circuitry comprises a plurality of semiconductor components and a plurality of transpinnors, each transpinnor comprising a network of thin-film elements, at least one thin-film element in each transpinnor exhibiting giant magnetoresistance, each transpinnor further comprising a conductor coupled to the at least one thin-film element for controlling operation of the transpinnor, wherein each transpinnor is operable to generate an output signal which is a function of a resistive imbalance among the thin-film elements and which is proportional to a power current in the network of thin-film elements.

11. The device of claim 11 wherein the plurality of semiconductor components comprises any of comparators, operational amplifiers, transresistance amplifiers, buffers, inverters, and bandgap regulators.

12. An embedded control system comprising the device of claim 1.

13. A real-time control system comprising the device of claim 1.

14. A general purpose computing system comprising the device of claim 1.

15. A nonvolatile sequential machine comprising a semiconductor controller operable to control operation of the nonvolatile sequential machine according to a state machine comprising a plurality of states, the nonvolatile sequential machine further comprising a plurality of state registers operable to store the plurality of states, the state registers comprising nonvolatile random-access memory operation of which is based on giant magnetoresistance.

16. The nonvolatile sequential machine of claim 15 wherein the state registers are operable to store the plurality of states during a reduced power mode of operation, the nonvolatile sequential machine further comprising a plurality of semiconductor registers operable to store the plurality of states during an active mode of operation, and interface circuitry operable to transmit the states between the semiconductor registers and the state registers.

17. The nonvolatile sequential machine of claim 16 wherein the interface circuitry is operable to transmit the states from the semiconductor registers to the state registers in response to an indication of a transition from the active mode to the reduced power mode.

18. The nonvolatile sequential machine of claim 16 wherein the interface circuitry is operable to transmit the states from the semiconductor registers to the state registers each time the semiconductor registers are updated.

19. The nonvolatile sequential machine of claim 16 wherein the interface circuitry is operable to transmit the states from the state registers to the semiconductor registers in response to an indication of a transition from the reduced power mode to the active mode.

20. The nonvolatile sequential machine of claim 16 wherein the reduced power mode comprises any of a standby mode, a power saving mode, a sleep mode, a power fault mode, and an off mode.

21. The nonvolatile sequential machine of claim 15 wherein the state registers comprise memory cells, access lines, and support electronics for facilitating access to information stored in the memory cells via the access lines, both the memory cells and the support electronics comprising multi-layer thin film structures exhibiting giant magnetoresistance.

22. The nonvolatile sequential machine of claim 21 wherein each of the memory cells comprises:
a plurality of magnetic layers, at least one of the magnetic layers being for magnetically storing one bit of information;
a plurality of the access lines integrated with the plurality of magnetic layers and configured such that the bit of information may be accessed using selected ones of the plurality of access lines and the giant magnetoresistive effect; and
at least one keeper layer;
wherein the magnetic layers, the access lines, and the at least one keeper layer form a substantially closed flux structure.

23. The nonvolatile sequential machine of claim 21 wherein the support electronics comprises a plurality of transpinnors, each transpinnor comprising a network of thin-film elements, at least one thin-film element in each transpinnor exhibiting giant magnetoresistance, each transpinnor further comprising a conductor coupled to the at least one thin-film element for controlling operation of the transpinnor, wherein each transpinnor is operable to generate an output signal which is a function of a resistive imbalance among the thin-film elements and which is proportional to a power current in the network of thin-film elements.

24. The nonvolatile sequential machine of claim 15 further comprising interface circuitry for translating signal levels between the semiconductor controller and the state registers.

25. The device of claim 24 wherein the interface circuitry comprises a plurality of semiconductor components and a plurality of transpinnors, each transpinnor comprising a network of thin-film elements, at least one thin-film element in each transpinnor exhibiting giant magnetoresistance, each transpinnor further comprising a conductor coupled to the at least one thin-film element for controlling operation of the transpinnor, wherein each transpinnor is operable to generate an output signal which is a function of a resistive imbalance among the thin-film elements and which is proportional to a power current in the network of thin-film elements.

26. The device of claim 25 wherein the plurality of semiconductor components comprises any of comparators, operational amplifiers, transresistance amplifiers, buffers, inverters, and bandgap regulators.

26. An embedded control system comprising the device of claim 15.

27. A real-time control system comprising the device of claim 15.

28. A general purpose computing system comprising the device of claim 15.
